(19) United States
(12) Patent Application Publication
(10) Pub. No.: US 2009/0078566 A1
(43) Pub. Date: Mar. 26, 2009

(54) Deposited Film Forming Method, Deposited Film Forming Device, Deposited Film, and Photosensitive Member Provided with the Deposited Film

(75) Inventors: Akihiko Ikeda, Higashiomi-shi (JP); Daigorou Ookubo, Higashiomi-shi (JP); Tetsuya Kawakami, Higashiomi-shi (JP); Takashi Nakamura, Higashiomi-shi (JP); Masamitsu Sasahara, Higashiomi-shi (JP); Daisuke Nagahama, Higashiomi-shi (JP); Tomomi Fukaya, Higashiomi-shi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 11/917,491

(22) PCT Filed: Jun. 1, 2006
(86) PCT No.: PCT/JP2006/311028

§ 371 Date: Dec. 13, 2007

(30) Foreign Application Priority Data
Jun. 16, 2005 (JP) 2005-176593

(51) Int. Cl. C23C 14/34; C23C 14/38; C01B 33/02; C01B 31/36; C01B 31/00

(52) U.S. Cl. 204/192.25; 204/298.08; 423/348; 423/345; 423/445 R

(57) ABSTRACT

The present invention relates to a method of forming a deposited film including a first step for setting a deposited film forming target (10) into a reaction chamber (4), a second step for filling the reaction chamber (10) with a reaction gas and a third step for applying pulse DC voltage between a first conductor (3) and a second conductor (40) spaced from each other in the reaction chamber (10). The present invention further relates to a deposited film forming device for performing the above method. Preferably, in the third step, potential difference between the first conductor (3) and the second conductor (40) is set to not less than 50V and not more than 3000V, and pulse frequency of the pulse DC voltage applied to the first and second conductors (3, 40) is set to not more than 300kHz. Duty ratio of the pulse DC voltage is set to not less than 20% and not more than 90%.

### TECHNICAL FIELD

The present invention relates to a technique for forming a deposited film, especially for forming an amorphous semiconductor film on an electrophotographic photosensitive member.

### BACKGROUND ART

Conventionally, an electrophotographic photosensitive member is made by forming a photoconductive layer and a surface layer as a deposited film on a surface of a cylindrical body. For forming a deposited film, in a widely-utilized method (plasma CVD method), a decomposition product produced by decomposing a material gas under high-frequency glow discharge is attached to the body.

In such a deposited film forming method, when increasing the depositing rate of the photoconductive layer and the surface layer of the electrophotographic photosensitive member, characteristics of the electrophotographic photosensitive member may be deteriorated. Recently, the electrophotographic photosensitive member has been required to have higher added value such as higher image quality, higher process speed, and higher durability. Thus, in order to meet requirements for the characteristics, it is inevitable to lower the film forming rate for improving the quality of film. On the other hand, when the depositing rate is lowered, manufacturing efficiency is deteriorated, and thus product cost is increased. For this reason, depositing rate of the photoconductive layer and the surface layer is normally set to 5 μm/h, when forming the layers using a-Si.

Meanwhile, in plasma CVD method, various technologies have been developed for achieving high film forming rate while reliably maintaining characteristics of the electrophotographic photosensitive member. As an example, a microwave plasma CVD method was developed (see Patent Documents 1, 2, for example).

In the method disclosed in Patent Document 1, deposited film is formed by applying microwave with frequency of 2.45 GHz to a depositing chamber for decomposing a material gas. In the method disclosed in Patent Document 2, while applying microwave to a discharge area in a reaction chamber, an electric field is generated between a part of a material gas supply means and a body. When using microwave, ionization degree of plasma is increased and thus plasma density is increased, so that deposited film is formed at a high depositing rate and a low internal stress. Especially when an electric field is generated in addition to microwave supply, ions in plasma are accelerated by the electric field and the kinetic energy is increased. Thus, stress in the film is lowered and deposited film with lower internal stress is formed.

In another developed method, high-frequency electricity with discharge frequency of 20 MHz is applied between first and second electrodes for generate discharge therebetween, while DC or AC bias voltage is applied to the first electrode serving as a processing target (see Patent Document 3, for example). In this method, by applying bias voltage, surface potential of the first electrode is brought to be uniform and stabilized, for preventing uneven distribution of plasma due to instability and non-uniformity of discharge at an area with low-powered high-frequency electricity, thereby improving film uniformity.

Patent Document 1: JP-A-60-186849

Patent Document 2: JP-A-3-219081

Patent Document 3: JP-A-8-225947

### DISCLOSURE OF THE INVENTION

However, in microwave plasma CVD method, it is difficult to obtain a uniform film because depositing rate differs at plasma irradiated region and unirradiated region and plasma is unevenly distributed. Especially when using a cylindrical body with a relatively large depositing area which is not irradiated entirely at once, a uniform film may not be formed. Further, when increasing frequency of voltage applied between the paired electrodes to more than 13.56 MHz, unstable and non-uniform discharge is generated. Thus, scratches are caused on the surface of the body or deposited film, and when foreign objects such as dust are attached to film, electric field concentrates on the scratches and the foreign objects, which causes defects on film.

Still further, when applying bias voltage (electric field) to discharge region between the paired electrodes, it may contribute to enhance film quality of the deposited film formed in high-rate film forming, however, it may simply deteriorate the quality of deposited film.

Specifically, when bias voltage applied to a discharge area is increased, arc discharge is likely to be generated in the discharge area. If arc discharge is generated, the whole electricity applied to the bias electrode of the body immediately concentrates on one portion, and may result in destruction of the body or deposited film on the body. Further, when such abnormal discharge is generated frequently, collision of active species to the body is not performed efficiently, thereby deteriorating repeatability of deposited film characteristics.

These disadvantages may be prevented by reducing the bias voltage applied to the paired electrodes, but reduce in bias voltage causes reduce in forming rate of deposited film. Thus, it is very difficult to increase the film forming rate while enhancing characteristics of film quality.

An object of the present invention is to prevent abnormal discharge such as arc discharge in film forming, and to perform high-rate film forming of deposited film with high quality without defects or variation in characteristics.

Another object of the present invention is to prevent defects such as black points in image forming using electrophotographic photosensitive member, for enhancing image characteristics.

According to a first aspect of the present invention, there is provided a method of forming a deposited film, comprising a first step for setting a deposited film forming target into a reaction chamber, a second step for filling the reaction chamber with a reaction gas, and a third step for applying pulse DC voltage between one or a plurality of first conductors and a second conductor spaced from each other in the reaction chamber.

In the third step, a potential difference between the first conductor and the second conductor is set to not less than 50V and not more than 3000V, preferably to not less than 500V and not more than 3000V, for example.

In the third step, frequency of the pulse DC voltage applied to the first conductor and the second conductor is set to not more than 300 kHz, for example.

In the third step, duty ratio of the pulse DC voltage applied to the first conductor and the second conductor is set to not less than 20% and not more than 90%, for example.

In the first step, the deposited film forming target may be supported by the first conductor. In this case, in the third step, the pulse DC voltage is applied to the first conductor, while the second conductor is maintained at ground potential or reference potential. Preferably, in the third step, pulse DC voltage of not less than −3000V and not more than −50V, or not less than 50V and not more than 3000V is applied to the first conductor, while the second conductor is maintained at ground potential.

In the first step, one or a plurality of cylindrical conductive bodies may be set in the reaction chamber as the deposited film forming targets. The cylindrical conductive body may be an electrophotographic photosensitive member.

In the first step, the plurality of conductive bodies is preferably arranged in the axial direction of the conductive bodies.

In the third step, the pulse DC voltage may be applied between the plurality of first conductors arranged in a circle and the second conductor which is a cylinder surrounding the first conductors.

In the third step, a central electrode positioned at a center portion surrounded by the first conductors may be maintained at ground potential or reference potential.

In the second step, the reaction chamber may have a reaction gas atmosphere in which an amorphous film containing silicon can be formed on the deposited film forming target.

In the second step, the reaction chamber may have a reaction gas atmosphere in which an amorphous film containing carbon can be formed on the deposited film forming target. In this case, in the third step, a negative pulse DC voltage is applied between the first conductor and the second conductor.

The second step may include a step in which the reaction chamber has a reaction gas atmosphere in which an amorphous film containing silicon can be formed on the deposited film forming target, as well as a step in which the reaction chamber has a reaction gas atmosphere in which an amorphous film containing silicon and carbon can be formed on the deposited film forming target. In this case, in the third step, a positive pulse DC voltage is applied between the first conductor and the second conductor when the reaction chamber has the reaction gas atmosphere in which an amorphous film containing silicon can be formed, while a negative pulse DC voltage is applied between the first conductor and the second conductor when the reaction chamber has the reaction gas atmosphere in which an amorphous film containing silicon and carbon can be formed.

According to a second aspect of the present invention, there is provided a deposited film forming device comprising a reaction chamber for accommodating a deposited film forming target, one or plurality of first conductors and a second conductor arranged in the reaction chamber, a gas supply means for supplying a reaction gas in the reaction chamber, a voltage apply means for applying DC voltage between each of the first conductors and the second conductor, and a controller for controlling the DC voltage applied by the voltage apply means to be pulse DC voltage.

The controller controls potential difference between the first conductor and the second conductor to be not less than 50V and not more than 3000V, preferably to be not less than 500V and not more than 3000V, for example.

The controller may control frequency of the pulse DC voltage applied to the first conductor and the second conductor to be not more than 300 kHz, and may also control duty ratio of the pulse DC voltage applied to the first conductor and the second conductor to be not less than 20% and not more than 90%.

The first conductor may support the deposited film forming target or one or a plurality of cylindrical conductive bodies as the deposited film forming targets. In this case, in the first conductor, the plurality of cylindrical conductive bodies may be arranged in the axial direction of the conductive bodies.

The controller may control to apply pulse DC voltage of not less than −3000V and not more than −50V, or not less than 50V and not more than 3000V to the first conductor. In this case, the second conductor is grounded.

The voltage apply means may apply pulse DC voltage between the plurality of first conductors and the second conductors. In this case, the second conductor may be cylindrical and surrounds the plurality of first conductors. The plurality of first conductors may be arranged in a circle, and the second conductor may be a cylinder.

The deposited film forming device according to the present invention may further comprise a central electrode positioned in the center of the first conductors. In this case, the controller controls the DC voltage applied by the voltage apply means to be pulse DC voltage, and the second conductor is maintained at ground potential or reference potential.

The deposited film forming device according to the present invention may be applied to form an electrophotographic photosensitive member.

The gas supply means may supply the reaction chamber with a reaction gas for forming amorphous film containing silicon on the deposited film forming target.

The gas supply means may supply the reaction chamber with a reaction gas for forming amorphous film containing carbon on the deposited film forming target. In this case, the controller applies a negative pulse DC voltage between the first conductor and the second conductor.

The gas supply means may supply the reaction chamber with a reaction gas for forming amorphous film containing silicon on the deposited film forming target, as well as with a reaction gas for forming amorphous film containing silicon and carbon on the deposited film forming target. In this case, the controller may apply a positive pulse DC voltage between the first conductor and the second conductor when the reaction chamber has the reaction gas atmosphere in which an amorphous film containing silicon can be formed, while applying a negative pulse DC voltage between the first conductor and the second conductor when the reaction chamber has the reaction gas atmosphere in which an amorphous film containing silicon and carbon can be formed.

The deposited film forming device according to the present invention may further comprise a discharge means for controlling gas pressure of the reaction gas in the reaction chamber.

According to a third aspect of the present invention, there is provide deposited film formed by the method of forming deposited film according to first aspect of the present invention.

The deposited film contains amorphous silicon (a-Si), amorphous silicon carbon (a-SiC), or amorphous carbon (a-C), for example.

According to a fourth aspect of the present invention, there is provided an electrophotographic photosensitive member comprising deposited film according to the third aspect of the present invention.

According to the present invention, arc discharge is prevented without reducing film forming rate, and a deposited film of high quality with less variation in characteristics can be formed at high-speed without increase in defects. Thus, deposited film of high quality with less variation in film thickness can be provided, and an electrophotographic photosensitive member having such a deposited film of high quality can be also provided.

### BRIEF DESCRIPTION OF THE DRAWINGS

FIG. 1 is a sectional view and an enlarged view of the principal portions, illustrating an example of an electrophotographic photosensitive member to be manufactured according to the present invention.

FIG. 2 is a vertical sectional view illustrating a deposited film forming device according to a first embodiment of the present invention.

FIG. 3 is a transverse sectional view illustrating the deposited film forming device of FIG. 2.

FIG. 4 is an enlarged view illustrating the principal portions of the deposited film forming device of FIGS. 1 and 2.

FIG. 5 is a graph illustrating a voltage application at the deposited film forming device of FIGS. 1 and 2.

FIG. 6 is a graph illustrating another voltage application at the deposited film forming device of FIGS. 1 and 2.

FIG. 7 is a vertical sectional view illustrating a deposited film forming device according to a second embodiment of the present invention.

FIG. 8 is a transverse sectional view illustrating the deposited film forming device of FIG. 7.

FIG. 9 is a graph illustrating measurement results of film forming rate in Example 3.

FIG. 10 is a graph illustrating measurement results of film forming rate in Example 4.

FIG. 11 is a graph illustrating measurement results of film thickness distribution at a-Si photosensitive drums in Example 5.

FIG. 12 is a graph illustrating measurement results of film forming rate in Example 8.

FIG. 13 is a graph illustrating measurement results of film forming rate in Example 9.

FIG. 14 is a graph illustrating measurement results of film thickness distribution at a-Si photosensitive drums in Example 10.

FIG. 15 is a graph illustrating measurement results of film forming rate in Example 13.

FIG. 16 is a graph illustrating measurement results of film forming rate in Example 14.

FIG. 17 is a graph illustrating measurement results of film thickness distribution at a-Si photosensitive drums in Example 15.

### LEGENDS

1 electrophotographic photosensitive member
10 cylindrical body (deposited film forming target)
11 anti-charge injection layer (deposited film)
12 photoconductive layer (deposited film)
13 surface layer (deposited film)
2 plasma CVD device (deposited film forming device)
3 supporting body (first conductor)
34 DC power source
35 controller
4 vacuum reaction chamber (reaction chamber)
40 cylindrical electrode (second conductor)
6 material gas supply means
7 discharge means
8 central electrode

### BEST MODE FOR CARRYING OUT THE INVENTION

A first and a second embodiments according to the present invention, taking an electrophotographic photosensitive member as an example, are described below with reference to the accompanied-drawings.

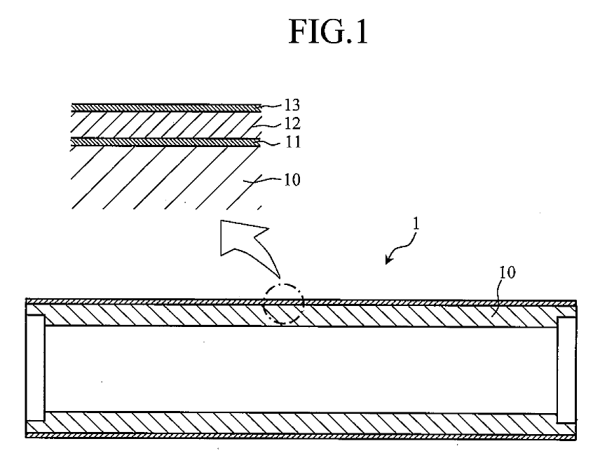

A first embodiment of the present invention will be described with reference to FIGS. 1 to 6.

An electrophotographic photosensitive member 1 illustrated in FIG. 1 includes a cylindrical body 10 having an outer circumference 10A on which an anti-charge injection layer 11, a photoconductive layer 12 and a surface layer 13 laminated in the mentioned order.

The cylindrical body 10 is the main body of the photosensitive member and is conductive at least at the surface. The cylindrical body 10 is made to be entirely conductive, using a metal material such as aluminum (Al), stainless-steel (SUS), zinc (Zn), copper (Cu), iron (Fe) titanium (Ti), nickel (Ni), chrome (Cr), tantalum (Ta) tin (Sn), gold (Au), and silver (Ag), or an alloy of the above-described metal materials, for example. The cylindrical body 10 may include an insulating body made of resin, glass, or ceramic, on which conductive film is provided using the above-described metal material or a transparent conductive material such as ITO and SnO₂. Among the above-described materials, Al material is most suitable for making the cylindrical body 10, and it is preferable to make the whole cylindrical body 10 by the Al material. In this way, the electrophotographic photosensitive member 1 with reduced weight can be manufactured at low cost. Further, when forming the anti-charge injection layer 11 and the photoconductive layer 12 by a-Si material, the adhesion between the layers and the cylindrical body 10 can be reliably enhanced.

The anti-charge injection layer 11 serves to prevent injection of carriers (electrons) from the cylindrical body 10, and is made of a-Si material, for example. Such anti-charge injection layer 11 contains boron (B), nitrogen (N), or oxygen (O) added as a dopant in the a-Si material, and has a thickness of not less than 2 μm and not more than 10 μm.

The photoconductive layer 12 serves to generate carriers by a laser irradiation, and is made of a-Si material or a-Se material such as Se—Te and As₂Se₃. In view of obtaining enhanced electrophotographic property (e.g. high photoconductivity, high-speed responsiveness, stable repeatability, high heat resistance, or high endurance) as well as conformity with the surface layer 13 when the surface layer 13 is made of a-Si material, it is preferable that the photoconductive layer 12 is made of a-Si, or a-Si material containing a-Si and carbon (C), nitrogen (N), or oxygen (O). The thickness of the photoconductive layer 12 may be set according to the photoconductive material and desired electrophotographic property. When the photoconductive layer 12 is made of a-Si material, the thickness of the photoconductive layer 12 is set to not less than 5 μm and not more than 100 μm, preferably to not less than 10 μm and not more than 80 μm.

The surface layer 13 serves to protect the surface of the electrophotographic photosensitive member 1, and for enduring to be grinded by rubbing in an image forming apparatus, is made of a-Si material such as a-SiC and a-SiN, or of a-C, for example. The surface layer 13 has a wide optical band gap for preventing absorption of light such as laser beams emitted to the electrophotographic photosensitive member 1, and also has a resistance (generally not less than 10¹¹Ω·cm) enabling to hold an electrostatic latent image in image forming.

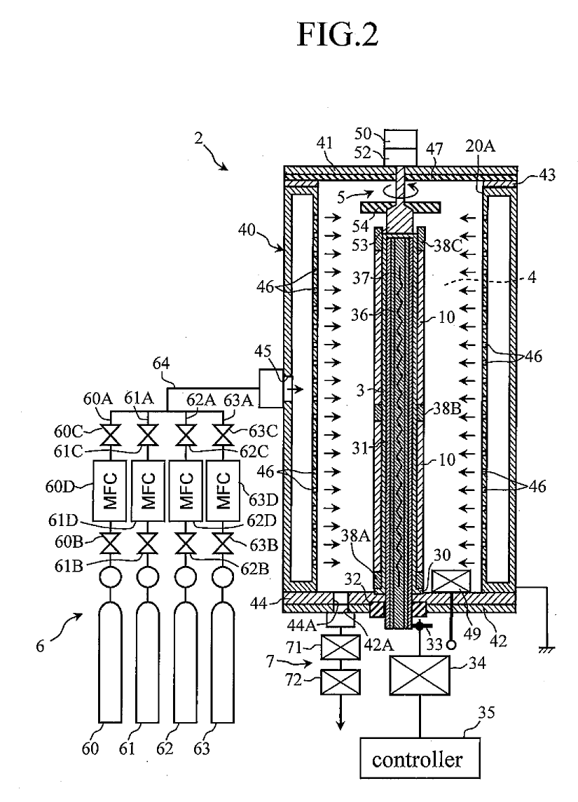

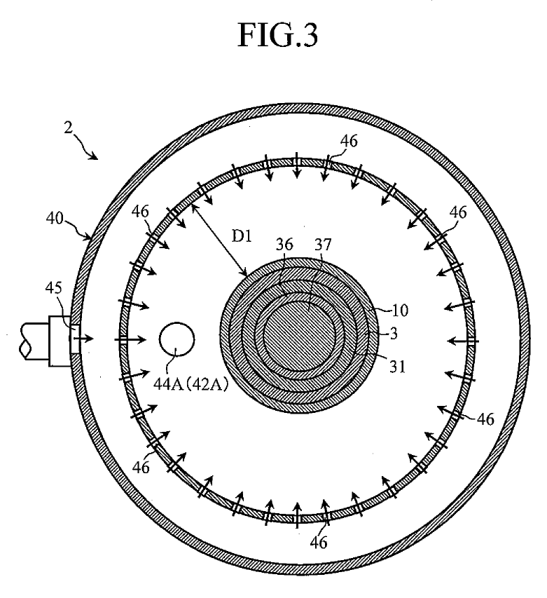

The anti-charge injection layer 11, the photoconductive layer 12, and the surface layer 13 of the electrophotographic photosensitive member 1 are formed by a plasma CVD device 2 shown in FIGS. 2 and 3, for example.

The plasma CVD device 2 includes a supporting body 3 accommodated in a vacuum reaction chamber 4, a rotation means 5, a material gas supply means 6, and a discharge means 7.

The supporting body 3 supports the cylindrical body 10 and serves as a first conductor. The supporting body 3 is a hollow member including a flange portion 30, and made of a conductive material similar to the cylindrical body 10, to be a conductor as a whole. The supporting body 3 has a length long enough for holding two cylindrical bodies 10, and is removable relative to a conducting cylinder 31. Thus, the supporting body 3 enables to insert and extract two cylindrical bodies 10 relative to the vacuum reaction chamber 4 without touching the surfaces of the cylindrical bodies 10.

The conducting cylinder 31 is made of a conductive material similar to the cylindrical body 10 to be a conductor as a whole, and fixed to a plate 42, which is to be described later, via an insulator 32 at the central portion of the vacuum reaction chamber 4 (or a cylindrical electrode 40 which is to be described later).

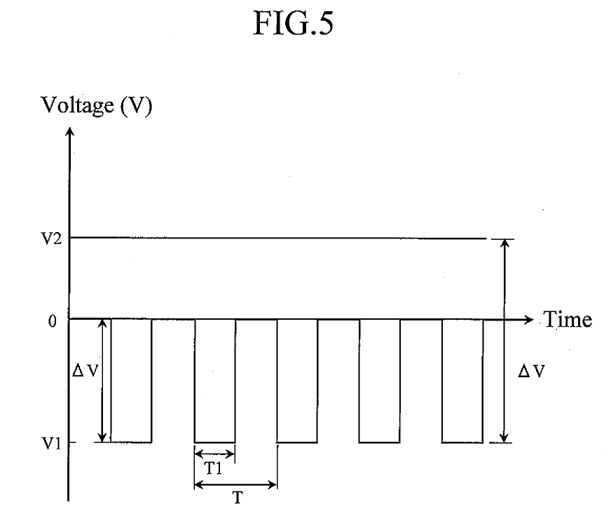

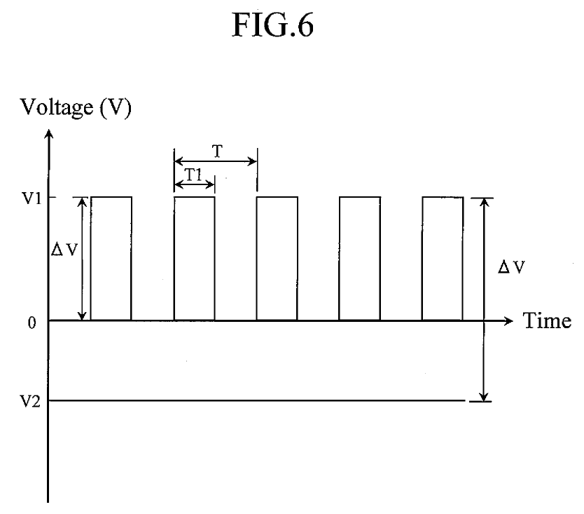

The conducting cylinder 31 is connected to a DC power source 34 via a conducting board 33. The DC power source 34 is controlled by a controller 35. The controller 35 controls the DC power source 34 to supply pulse DC voltage to the supporting body 3 via the conducting cylinder 31 (see FIGS. 5 and 6).

The conducting cylinder 31 accommodates a ceramic pipe 36 and a heater 37 in the pipe. The ceramic pipe 36 provides insulating property and heat conductivity. The heater 37 heats the cylindrical body 10. Examples of the heater 37 include nichrome wire and a cartridge heater.

Here, the temperature of the supporting body 3 is monitored by a thermocouple (not shown) attached to the conducting cylinder 31, and based on the monitoring result of the thermocouple, the heater 37 is switched on and off. In this way, the temperature of the cylindrical body 10 is maintained within a predetermined range of not less than 200° C. to not more than 400° C., for example.

The vacuum reaction chamber 4 provides a space for forming deposited film on the cylindrical body 10, and is defined by a cylindrical electrode 40 and a pair of plates 41, 42.

The cylindrical electrode 40 is a cylinder surrounding the supporting body 3 and serves as a second conductor. The cylindrical electrode 40 is made of a conductive material similar to the cylindrical body 10 to have a hollow portion, and connected to the paired plates 41, 42 via insulating members 43, 44.

The dimension of the cylindrical electrode 40 is set so that a distance D5 between the cylindrical body 10 held by the supporting body 3 and the cylindrical electrode 40 is made to be not less than 10 mm and not more than 100 mm. This is because if the distance D5 between the cylindrical body 10 and the cylindrical electrode 40 is smaller than 10 mm, the cylindrical body 10 cannot be smoothly inserted and extracted relative to the vacuum reaction chamber 4, and it is difficult to perform stable discharge between the cylindrical body 10 and the cylindrical electrode 40. Meanwhile, if a distance D1 between the cylindrical body 10 and the cylindrical electrode 40 is larger than 100 mm, the dimension of the plasma CVD device 2 is increased and thus the productivity per unit installation area is lowered.

The cylindrical electrode 40 is provided with a gas inlet port 45 and a plurality of gas outlet ports 46, and grounded at one end. The cylindrical electrode 40 is not necessarily grounded, and may be connected to a reference supply other than the DC power source 34. If the cylindrical electrode 40 is connected to a reference supply other than the DC power source 34, when a negative pulse voltage is applied to the supporting body 3 (or the cylindrical body 10) as shown in FIG. 5, the reference voltage at the reference supply is set to not less than −1500V and not more than 1500V, while when a positive pulse voltage is applied to the supporting body 3 (or the cylindrical body 10) as shown in FIG. 6, the reference voltage is set to not less than −1500V and not more than 1500V.

The gas inlet port 45 serves to introduce the material gas to be supplied to the vacuum reaction chamber 4, and is connected to the material gas supply means 6.

The gas outlet ports 46 serve to spray the material gas introduced into the cylindrical electrode 40 toward the cylindrical body 10, and are arranged at regular intervals in the vertical direction in the figure as well as in the circumferential direction. The gas outlet ports 46 are equally formed into a circle having a diameter of not less than 0.5 mm and not more than 2.0 mm, for example. Of course, the diameter, the shape, and the arrangement of the gas outlet ports 46 may be changed.

The plate 41 enables to select between the opened and closed states of the vacuum reaction chamber 4, and by opening the plate 41, the supporting body 3 can be inserted or extracted relative to the vacuum reaction chamber 4. The plate 41 is made of a conductive material similar to the cylindrical body 10 and is provided with a prevention board 47 at the lower surface for preventing deposited film from being formed at the plate 41. The prevention board 47 is also made of a conductive material similar to the cylindrical body 10. The prevention board 47 is removable relative to the plate 41. The prevention board 47 can be washed by removing from the plate 41, and thus used repeatedly.

The plate 42 serves as a base of the vacuum reaction chamber 4, and made of a conductive material similar to the cylindrical body 10. The insulating member 44 is positioned between the plate 42 and the cylindrical electrode 40 to prevent arc discharge from being generated between the cylindrical electrode 40 and the plate 42. Such insulating member 44 is made of a glass material (e.g. borosilicate glass, soda glass, or heat-resistant glass), an inorganic insulating material (e.g. ceramics, quartz, or sapphire), or a synthetic resin insulating material (e.g. fluorine resin such as Teflon (registered mark), polycarbonate, polyethylene terephthalate, polyester, polyethylene, polypropylene, polystyrene, polyamide, vinylon, epoxy, mylar, or PEEK (polyether ether ketone)), though not limited to these, and an insulating material may be used, if it has high use temperature and releases only a little gas in vacuum. The insulating member 44 has a thickness larger than a predetermined amount in order to prevent fatal warp due to stress generated by bimetallic effect caused according to inner stress of film and temperature increase in film forming. For example, when making the insulating member 44 using a material having a thermal expansion rate of not less than 3×10−5/K and not more than 10×105/K, such as Teflon (registered mark), the thickness of the insulating member 44 is set to not less than 10 mm. By setting the thickness of the insulating member 44 to such amount, the degree of warp due to stress generated at the boundary face between the insulating member 44 and a-Si film formed on the cylindrical body 10 can be reduced. When the a-Si film has a thickness of not less than 10 μm and not more than 30 μm, the degree of warp can be reduced to not more than 1 mm in difference between the heights at the edge and at the central portion, per 200 mm length of the insulating member, as seen in the transverse direction (the radial direction perpendicular to the axial direction of the cylindrical body 10), whereby the insulating member 44 can be used repeatedly.

The plate 42 and the insulating member 44 are provided with respective gas discharge ports 42A, 44A and a manometer 49. The gas discharge ports 42A, 44A serve to discharge gas from the vacuum reaction chamber 4, and are connected to the discharge means 7. The manometer 49 monitors the pressure in the vacuum reaction chamber 4, and various known manometers can be used.

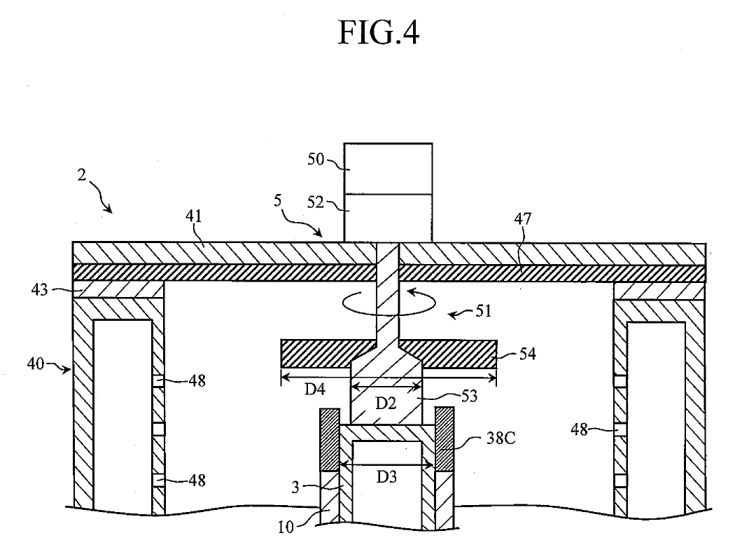

As shown in FIG. 4, the rotation means 5 serves to rotate the supporting body 3 and includes a rotation motor 50 and a rotation transfer mechanism 51. By rotating the supporting body 3 using the rotation means 5 in film forming, since the cylindrical body 10 is rotated together with the supporting body 3, decomposed components of material gas can be uniformly deposited to the outer circumference of the cylindrical body 10.

The rotation motor 50 serves to provide rotation to the cylindrical body 10. The rotation motor 50 is controlled to rotate the cylindrical body 10 at not less than 1 rpm and not more than 10 rpm. Various known rotation motors can be used as the rotation motor 50.

The rotation transfer mechanism 51 serves to transfer and input the rotation of the rotation motor 50 to the cylindrical body 10, and includes a rotation input terminal 52, an insulating shaft 53, and an insulating board 54.

The rotation input terminal 52 serves to transfer the rotation, while keeping the vacuum state in the vacuum reaction chamber 4. An example of such rotation input terminal 52 includes a vacuum seal such as oil seal and mechanical seal having a double or triple rotation shaft.

The insulating shaft 53 and the insulating board 54 serve to input the rotation from the rotation motor 50 to the supporting body 3, while keeping the insulation between the supporting body 3 and the plate 41, and are made of an insulating material similar to the insulating member 44. Here, the outer diameter D3 of the insulating shaft 53 (or the inner diameter of an upper dummy body 38C which is to be described later) is set to be smaller than the outer diameter of the supporting body 3 during the film forming. Specifically, when the temperature of the cylindrical body 10 in film forming is set to not less than 200° C. to not more than 400° C., the outer diameter D2 of the insulating shaft 53 is set to be smaller than the outer diameter of the supporting body 3 (or the inner diameter D3 of the upper dummy body 38C which is to be described later) by not less than 0.1 mm and not more than 5 mm, preferably by about 3 mm. In order to meet the conditions, when film is not formed (under thermally neutral environment with temperature of not less than 10° C. and not more than 40° C., for example), the difference between the outer diameter of the insulating shaft 53 and the outer diameter D3 of the supporting body 3 (or the inner diameter of the upper dummy body 38C which is to be described later) is set to be not less than 0.6 mm and not more than 5.5 mm.

The insulating board 54 serves to prevent adhesion of foreign objects such as dirt and dust falling from above when removing the plate 41, and is formed into a circular plate having a diameter D4 larger than the inner diameter D3 of the upper dummy body 38C. The diameter b4 of the insulating board 54 is set to be larger than the diameter D3 of the cylindrical body 10 at a ratio of not less than 1.5 to 1 and not more than 3.0 to 1. When the diameter D3 of the cylindrical body 10 is 30 mm, the diameter D4 of the insulating board 54 is set to about 50 mm, for example.

With such insulating board 54, abnormal electrical discharge, due to the foreign objects adhering to the cylindrical body 10, can be prevented, and thus defects in film forming can be prevented. In this way, the yield of the electrophotographic photosensitive member 1 can be increased, and defective image can be prevented in image forming using the electrophotographic photosensitive member 1.

As shown in FIG. 2, the material gas supply means 6 includes a plurality of material gas tanks 60, 61, 62, 63, a plurality of gas pipes 60A, 61A, 62A, 63A, a plurality of valves 60B, 61B, 62B, 63B, 60C, 61C, 62C, 63C, and a plurality of mass flow controllers 60D, 61D, 62D, 63D, and is connected to the cylindrical electrode 40 via a pipe 64 and the gas inlet port 45. The material gas tanks 60-63 are filled with B₂H₆, H₂ (or He), CH₄, or SiH₄, for example. The valves 60B-63B, 60C-63C and the mass flow controllers 60D-63D serve to control flow rate, composition, and gas pressure of material gas to be introduced into the vacuum reaction chamber 4. Of course, in the material gas supply means 6, the type of the gas to be filled in the material gas tanks 60-63 and the number of the material gas tanks 60-63 may be selected according to the type or the composition of the film to be formed on the cylindrical body 10.

The discharge means 7 serves to discharge the gas in the vacuum reaction chamber 4 through the gas discharge ports 42A, 44A, and includes a mechanical booster pump 71 and a rotary pump 72. These pumps 71, 72 are controlled according to the monitoring result of the manometer 49. Specifically, with the discharge means 7, based on the monitoring result of the manometer 49, the vacuum state in the vacuum reaction chamber 4 is maintained, and the gas pressure in the vacuum reaction chamber 4 is set to a desired value. The pressure in the vacuum reaction chamber 4 is set to not less than 1.0 Pa and not more than 100 Pa, for example.

Next, a forming method of deposited film using the plasma CVD device will be described, exemplifying the electrophotographic photosensitive member 1 (see FIG. 1) in which the cylindrical body 10 is formed with a-Si film.

First, on forming deposited film (a-Si film) on the cylindrical body 10, the plate 41 of the plasma CVD device is removed, and a plurality of cylindrical bodies 10 (two of them are illustrated in the figure) supported by the supporting body 3 are positioned within the vacuum reaction chamber 4, and then the plate 41 is attached.

In supporting the two cylindrical bodies 10 by the supporting body 3, the supporting body 3 is covered by a lower dummy body 38A, the cylindrical body 10, another cylindrical body 10, and an upper dummy body 38B stacked on the flange portion 30 in the mentioned order.

In supporting the two cylindrical bodies 10 by the supporting body 3, the supporting body 3 is covered by a lower dummy body 38A, the cylindrical body 10, an intermediate dummy body 38B, another cylindrical body 10, and an upper dummy body 38C stacked on the flange portion 30 in the mentioned order.

Each of the dummy bodies 38A-38C are selected from a conductive body or an insulting body provided with a conductive surface, according to use of the photosensitive member to be made, and normally made into cylinders using the same material as the cylindrical body 10.

The lower dummy body 38A adjusts the height of the cylindrical body 10. The intermediate dummy body 38B prevents defective film form being formed at the cylindrical body 10 due to arc discharge generated between the adjacent cylindrical bodies 10. The intermediate dummy body 38B has a length not less than a minimum length required for preventing arc discharge (1 cm in the present embodiment), and outer ends which are curved at a curvature of not less than 0.5 mm or cut into chamfers with lengths of not less than 0.5 mm in the axial direction and in depth. The upper dummy body 38C prevents deposited film from being formed on the supporting body 3, and also prevents defective film which is caused when the formed film peels off during the film forming. The upper dummy body 38C partly protrudes above the supporting body 3.

Next, the vacuum reaction chamber 4 is sealed and the cylindrical body 10 is rotated by the rotation means 5 together with the supporting body 3. Then, the cylindrical body 10 is heated, while the vacuum reaction chamber 4 is decompressed by the discharge means 7.

An external power is supplied to generate heat at the heater 37, and the cylindrical body 10 is heated by the heater 37. Such heat generation at the heater 37 raises the temperature of the cylindrical body 10 to a desired temperature. The temperature of the cylindrical body 10 is selected according to the type and the composition of the film to be formed on the surface of the body. For example, when forming a-Si film, the temperature is set to not less than 250° C. and not more than 300° C., and maintained to be substantially constant by switching the heater 37 on and off.

The vacuum reaction chamber 4 is decompressed by the discharge means 7 which discharges gas from the vacuum reaction chamber 4 through the gas discharge ports 42A, 44A. The pressure in the vacuum reaction chamber 4 is reduced by about 10-3 Pa, for example, by monitoring the pressure in the vacuum reaction chamber 4 using the manometer 49 (see FIG. 2) and controlling the mechanical booster pump 71 (see FIG. 2) and the rotary pump 72 (see FIG. 2).

Accordingly, when the temperature of the cylindrical body 10 is set to a desired temperature and the pressure in the vacuum reaction chamber 4 is set to a desired pressure, material gas is supplied into the vacuum reaction chamber 4 by the material gas supply means 6, and pulse DC voltage is applied across the cylindrical electrode 40 and the supporting body 3. Then, a glow discharge is generated between the cylindrical electrode 40 and the supporting body 3 (or the cylindrical body 10), and material gas composition is decomposed, so that the decomposed components of the material gas are deposited on the surface of the cylindrical body 10.

Meanwhile, in the discharge means 7, by monitoring using the manometer 49 and controlling the mechanical booster pump 71 and the rotary pump 72, the gas pressure in the vacuum reaction chamber 4 is maintained within a desired range. The gas pressure in the vacuum reaction chamber 4 is stabilized by the mass flow controllers 60D-63D of the material gas supply means 6 and the pumps 71, 72 of the discharge means 7. The gas pressure in the vacuum reaction chamber 4 is set to not less than 1.0 Pa and not more than 100 Pa, for example.

In supplying material gas to the vacuum reaction chamber 4, by opening and closing the valves 60B-63B, 60C-63C while controlling the mass flow controllers 60D-63D, material gas is introduced at a desired composition and flow rate from the material gas tanks 60-63 into the cylindrical electrode 40 through the pipes 60A-63A, 64 and the gas inlet port 45. The material gas introduced into the cylindrical electrode 40 is sprayed out toward the cylindrical body 10 through the gas outlet ports 46. By changing composition of the material gas using the valves 60B-63B, 60C-63C and the mass flow controllers 60D-63D, the outer circumference 10A of the cylindrical body 10 is formed with the anti-charge injection layer 11, the photoconductive layer 12, and the surface layer 13.

Application of the pulse DC voltage across the cylindrical electrode 40 and the supporting body 3 is performed by controlling the DC power source 34 using the controller 35.

Generally, when high-frequency electricity is applied within the RF band of not less than 13.56 MHz, ion species generated in the air are accelerated by the electric field, and drawn in a direction corresponding to the positive or negative pole. However, since the electric field is continually reversed due to high-frequency AC, the ion species repeat recombination in the air before arriving at the cylindrical body 10 or the discharging electrode, and are discharged as gas or a silicon compound such as polysilicon powder.

On the other hand, when applying pulse DC voltage to the cylindrical body 10 to have positive or negative polarity, cations are accelerated to bump into the cylindrical body 10, and the impact of the bump can be used for sputtering fine irregularities at the surface of the body while forming a-Si film. In this way, a-Si film having a surface with very little irregularities can be obtained. The inventor named this phenomenon as “ion sputtering effect”.

In such plasma CVD method, in order to efficiently obtain the ion sputtering effect, it is necessary to apply electric power in a manner that continual reversal of polarity is prevented, for which triangular wave, DC power, and DC voltage is usable in addition to the above pulse rectangular wave. Further, AC power can be also used if the whole voltage is adjusted to have either of positive and negative polarity. The polarity of the applied voltage can be freely changed in consideration of film forming rate which depends on ion species density and polarity of deposited species, corresponding to the type of material gas.

Further, in order to efficiently obtain the ion sputtering effect utilizing pulse voltage, potential difference between the supporting body 3 (or the cylindrical body 10) and the cylindrical electrode 40 is set to not less than 50V and not more than 3000V, for example, and in consideration of the forming rate, it is preferable to set the potential difference to not less than 500V and not more than 3000V.

Specifically, when the cylindrical electrode 40 is grounded, the controller 35 supplies negative pulse DC potential V1 in the range of not less than −3000V to not more than −50V (see FIG. 5) or positive pulse DC potential V1 in the range of not less than 50V to not more than 3000V (see FIG. 6), to the supporting body 3 (or the conducting cylinder 31).

When the cylindrical electrode 40 is connected to the reference supply (not shown), the pulse DC potential V1 to be supplied to the supporting body (or the conducting cylinder 31) is a value (ΔV-V2) obtained by subtracting electrical potential V2 supplied by the reference supply from a desired electrical potential difference ΔV. When negative pulse voltage is applied to the supporting body 3 (or the cylindrical body 10) as shown in FIG. 5, the electrical potential V2 supplied by the reference supply is set to be in the range of not less than −1500V to not more than 1500V, while when positive pulse voltage is applied to the supporting body 3 (or the cylindrical body 10) as shown in FIG. 6, the electrical potential V2 is set to be in the range of not less than −1500V to not more than 1500V.

The controller 35 also serves to set frequency of DC voltage (1/T (sec)) to not more than 300 kHz, and duty ratio (T1/T) to not less than 20% and not more than 90%, by controlling the DC power source 34.

Here, as shown in FIGS. 5 and 6, the duty ratio in the present invention is defined as a ratio of potential difference generating time T1 to one period (T) of pulse DC voltage (period from the moment potential difference is generated across the cylindrical body 10 and the cylindrical electrode 40 to the moment the next potential difference is generated). For example, when the duty ratio is 20%, the potential difference generating time (ON time) T1 in one period accounts for 20% of the one period T in pulse voltage application.

By utilizing the ion sputtering effect in forming the a-Si photoconductive layer 12, even if the thickness of the layer is not less than 10 μm, fine irregularities at the surface are finer and the smoothness is hardly deteriorated. Thus, when a-SiC film is laminated on the photoconductive layer 12 to form the surface layer 13, the surface of the surface layer 13 can be a smooth surface benefiting from the smoothness of the photoconductive layer 12. Further, by utilizing the ion sputtering effect in forming the surface layer 13, the surface layer 13 can also have a smooth surface with finer irregularities.

As described above, in forming the anti-charge injection layer 11, the photoconductive layer 12, and the surface layer 13, the mass flow controllers 60D-63D and the valves 60B-63B, 60C-63C of the material gas supply means 6 are controlled to supply material gas with desired composition to the vacuum reaction chamber 4.

For example, when forming the anti-charge injection layer 11 as a-Si deposited film, the material gas may be Si-containing gas such as SiH₄ (silane gas) dopant-containing gas such as B₂H₆, or mixed gas of diluent gases such as hydrogen (H₂) and helium (He). Examples of the dopant-containing gas may include, in addition to boron-containing gas (B), nitrogen (N) and oxygen (O).

When forming the photoconductive layer 12 as a-Si deposited film, the material gas may be Si-containing gas such as SiH₄ (silane gas) or mixed gas of diluent gases such as hydrogen (H₂) and helium (He). In forming the photoconductive layer 12, hydrogen gas may be used as the diluent gas or a halogen compound may be contained in the material gas, so that hydrogen (H) or a halogen element (F, Cl) may be contained in the film by not less than one atom % and not more than 40 atom % for dangling-bond termination. Further, for obtaining a desired property such as electrical property including e.g. dark conductivity and photoconductivity as well as optical bandgap, the material gas may contain a thirteenth group element of the periodic system (hereinafter referred to as “thirteenth group element”) or a fifteenth group element of the periodic system (hereinafter referred to as “fifteenth group element”) or carbon (C) or oxygen (O) may be also contained.

As the thirteenth group element and the fifteenth group element, it is desired to use boron (B) and phosphorus (P) in view of high covalence and sensitive change of semiconductor property, as well as of high luminous sensitivity. When the thirteenth group element and the fifteenth group element are contained in combination with elements such as carbon (C) and oxygen (O) in forming the anti-charge injection layer 11, preferably, the thirteenth group element may be contained by not less than 0.1 ppm and not more than 20000 ppm, while the fifteenth group element may be contained by not less than 0.1 ppm and not more than 10000 ppm. Further, when the thirteenth group element and the fifteenth group element are contained in combination with elements such as carbon (C) and oxygen (O) in forming the photoconductive layer 12, or when elements such as carbon (C) and oxygen (O) are not contained in forming the anti-charge injection layer 11 and the photoconductive layer 12, the thirteenth group element may be contained by not less than 0.01 ppm and not more than 200 ppm, while the fifteenth group element may be contained by not less than 0.01 ppm and not more than 100 ppm. The amount of the thirteenth group element and the fifteenth group element contained in the material gas may be changed with time so that concentration gradient is generated in the film thickness. In this case, the amount of the thirteenth group element and the fifteenth group element in the photoconductive layer 12 is set so that the average content in the photoconductive layer 12 is within the above-described range.

In forming the photoconductive layer 12 using a-Si material, microcrystal silicon (μc-Si) may be contained, which enhances dark conductivity and photoconductivity, and thus advantageously increases design freedom of the photoconductive layer 12. Such μc-Si can be formed by utilizing a method similar to the above-described method, and by changing film forming conditions. For example, when utilizing glow discharge decomposition method, the layer can be formed by setting the temperature and pulse DC electric power at the cylindrical body 10 to be relatively high, and by increasing flow amount of hydrogen as diluent gas. Further, elements similar to the above-described elements (the thirteenth group element and the fifteenth group element, carbon (C), and oxygen (O)) may also be added when forming the photoconductive layer 12 containing μc-Si.

When forming the surface layer 13 as a-SiC deposited film, the material gas may be Si-containing gas such as SiH4 (silane gas) and mixed gas of C containing gases such as CH4. The component ratio of Si to C in the material gas may be changed continuously or intermittently. Specifically, since the forming rate tends to be lowered as the ratio of C is increased, in forming the surface layer 13, the ratio of C is reduced at a region of the surface layer 13 near the photoconductive layer 12, whereas the ratio of C is increased at the side of the free surface. For example, the surface layer 13 may have a double-layered structure by depositing a first SiC layer, on the photoconductive layer 12 (or the boundary surface), containing relatively large amount of Si in which the value X (carbon atom ratio) in amorphous hydrogenated silicon carbide (a-Si₁₋ₓ Cₓ:H) is set to more than 0 and less than 0.8, and then forming thereon a second SiC layer containing an increased amount of C in which the value X (carbon atom ratio) is set to not less than 0.95 and less than 1.0.

The thickness of the first SiC layer is determined in consideration of pressure resistance, residual potential, and strength of film, to be normally not less than 0.1 μm and not more than 2.0 μm, preferably not less than 0.2 μm and not more than 1.0 μm, and most preferably, not less than 0.3 μm and not more than 0.8 μm. The thickness of the second SiC layer is determined in consideration of pressure resistance, residual potential, strength of film, and life period (wear resistance), to be normally not less than 0.01 μm and not more than 2.0 μm, preferably not less than 0.02 μm and not more than 0.8 μm, and most preferably, not less than 0.05 μm and not more than 0.8 μm.

The surface layer 13 may be formed as a-C layer as described above. In this case, the material gas is C containing gas such as C₂H₂ (acethylene gas) and CH4 (methane gas). Such surface layer 13 has a thickness of normally not less than 0.1 μm and not more than 2.0 μm, preferably not less than 0.2 μm and not more than 1.0 μm, and most preferably, not less than 0.33 μm and not more than 0.8 μm.

When the surface layer 13 is formed as a-C layer, since the binding energy of C—O binding is larger than Si—O binding, oxidization of the surface of the surface layer 13 is more reliably prevented than when the surface layer 13 is formed of a-Si material. Specifically, when the surface layer 13 is formed as a-C layer, since e.g. ozone is generated by corona discharge during printing, oxidization of the surface of the surface layer 13 is suitably prevented, thereby preventing image deletion due to the environment with high temperature and humidity.

When the film forming of the cylindrical body 10 is finished, the cylindrical body 10 is removed from the supporting body 3, and the electrophotographic photosensitive member 1 shown in FIG. 1 is obtained. After the film forming, in order to remove residues, members of the vacuum reaction chamber 4 are disassembled and undergo acid cleaning, alkali cleaning, or blast cleaning. Then, wet etching is performed to prevent generation of dust which may cause a defect in the next film forming. In place of wet etching, gas etching may be performed using a halogen gas (ClF₃, CF₄, NF₃, SiF₆ or mixed gas of these gases) or O₂ gas.

According to the present invention, arc discharge generated during film forming is prevented without reducing film forming rate, and high quality deposited film (the anti-charge injection layer 11, the photoconductive layer 12, and the surface layer 13) with less variation in property and less defect is formed at high speed. Thus, high quality deposited film with less variation in film thickness is provided, and the electrophotographic photosensitive member 1 is also provided with such high quality deposited film.

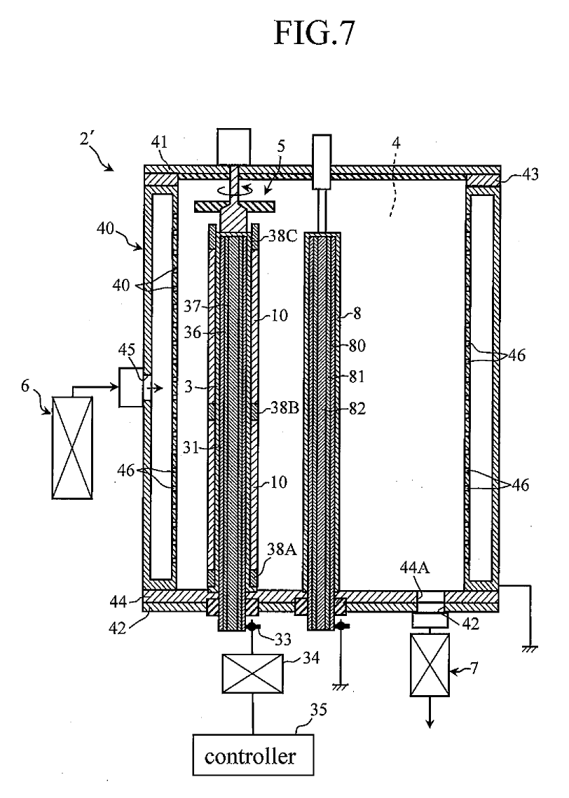

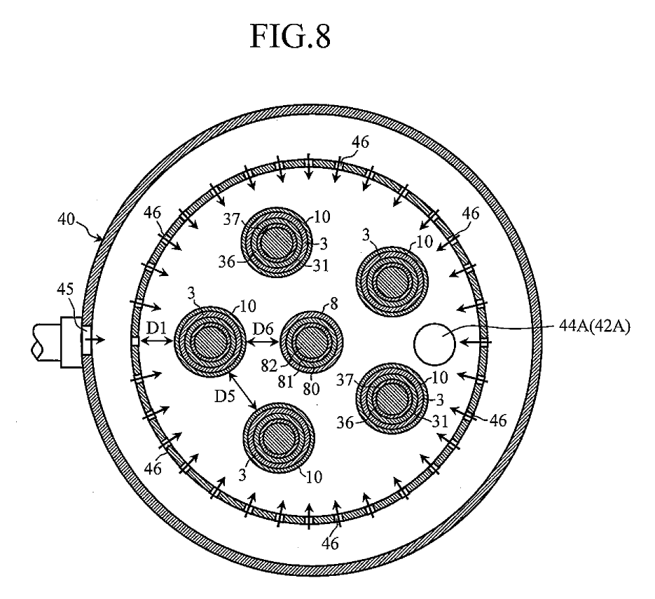

Next, a second embodiment of the present invention will be described with reference to FIGS. 7 and 8. In FIGS. 7 and 8, elements identical or similar to the electrophotographic photosensitive member 1 and the plasma CVD device 2 described already with reference to FIGS. 1 to 6 are given the same reference numbers and duplicated description will be omitted.

The plasma CVD device 2′ illustrated in FIGS. 7 and 8 includes a central electrode 8 positioned in the center of a vacuum reaction chamber 4 (a cylindrical electrode 40), and a plurality of supporting bodies 3 surrounding the central electrode 8.

The supporting bodies 3 are arranged in a circle concentric with the central electrode 8, spaced from each other at a distance D5. Each of the supporting bodies 3 and the central electrode 8 are spaced from each other at a distance D6. The supporting bodies 3 are connected to a DC power source 34, and pulse DC voltage is simultaneously supplied to the supporting bodies 3 by the DC power source 34. However, each of the supporting bodies 3 may be connected to an individual DC power source 34.

Similarly to the cylindrical electrode 40, the central electrode 8 generates potential difference between each of the supporting bodies 3 (or cylindrical bodies 10) and the central electrode. In order to efficiently obtain the ion sputtering effect and to form deposited film with little irregularities, pulse DC voltage is applied to the supporting bodies 3 and the central electrode 8 by controlling the DC power source 34 using a controller 35. The potential difference is set to, similarly to that between the cylindrical electrode 40 and the supporting body 3, not less than 50V and not more than 3000V, for example. The frequency is set to not more than 300 kHz, and the duty ratio is set to not less than 20% and not more than 90%.

Such central electrode 8 is a hollow conductor as a whole, made of a conductive material similarly to the cylindrical bodies 10 and the supporting bodies 3. The central electrode 8 includes a conducting cylinder 80, ceramic pipe 81, and a heater 82.

The conducting cylinder 80 is a conductor as a whole, made of a conductive material similarly to the cylindrical bodies 10, and is fixed to a plate 42 via an insulator 83 at the center of the vacuum reaction chamber 4 (the cylindrical electrode 40 which is to be described later). The conducting cylinder 80 is grounded so that the central electrode 8 provides ground potential. Of course, the conducting cylinder 80 may be connected to a reference power supply other than the DC power source 34, and the central electrode 8 may be directly connected to the ground, or the central electrode 8 may be directly connected to a reference power supply.

The ceramic pipe 81 is for insulation and heat conduction. The heater 82 heats the central electrode 8. Examples of the heater 82 include, similarly to the heater 37 for heating the cylindrical bodies 10, nichrome wire and a cartridge heater, for example. In this case, the heater 37 for heating the cylindrical bodies 10 and the heater 82 for heating the central electrode 8 may be driven individually, however, for simplification of the structure, it is preferable to drive the heaters 37, 82 simultaneously.

Here, the heater 82 for heating the central electrode 8 has a heating capacity set to not less than 25% and not more than 90% of the heating capacity of the heater for the cylindrical bodies 10. If the heaters 37, 82 are driven simultaneously and the heating capacity of the heater 82 is the same or larger than that of the heater 37, the temperature at the central electrode 8 is increased faster than at each of the supporting bodies 3. Thus, before the temperature at the supporting body 3 holding the cylindrical bodies 10 is increased adequately, a temperature monitor (thermocouple) provided around the supporting body 3 detects the temperature at the central electrode 8, and the heaters 37, 82 may stop heating. On the other hand, if the heating capacity of the heater 82 is much smaller than that of the heater 37, when the temperature monitor (thermocouple) detects adequate temperature rise at the central electrode 8, the temperature at the cylindrical bodies 10 may get too high.

The heating capacity of the heater 37 is set to not less than 240 W and not more than 400 W, while the heating capacity of the heater 82 is set to not less than 60 W and not more than 360 W, under the conditions: the distance D4 between the adjacent cylindrical bodies 10 is not less than 10 mm and not more than 50 mm, while the distance D5 between each of the cylindrical bodies 10 and the central electrode 8 is not less than 10 mm and not more than 30 mm; and the reaction gas pressure at the vacuum reaction chamber 4 is not less than 13.3 Pa and not more than 133 Pa.

In the plasma CVD device 2′, by controlling the DC power source 34 using the controller 35, pulse DC voltage is applied between each of the supporting bodies 3 (the cylindrical bodies 10) and the cylindrical electrode 40, and between each of the supporting bodies 3 (the cylindrical bodies 10) and the central electrode 8. In this way, glow discharge is generated between the supporting bodies 3 and the cylindrical electrode 40 as well as the central electrode 8. As a result, by generating the glow discharge in the vacuum reaction chamber 4 in which a material gas is supplied, deposited film is formed on the surface of the cylindrical bodies 10.

The present invention is not limited to the above-described embodiments, and may be variously changed and modified without departing from the scope of the present invention.

For example, in the above embodiment, the cylindrical electrode 40 as the second conductor is used to supply a material gas into the vacuum reaction chamber 4. However, a gas inlet port may be provided separately from the cylindrical electrode 40, to be used for introducing a material gas into the vacuum reaction chamber 40. As the gas inlet port, a conventional gas inlet port is preferably used. The gas inlet port is positioned in the vacuum reaction chamber 4, between each of the cylindrical bodies 10 and the cylindrical electrode 40, or between each of the cylindrical bodies 10 and the central electrode 8.

Further, the present invention may also be applied when forming deposited film on a body other than a cylindrical body to make an electrophotographic photosensitive member, or when forming deposited film on a body for a purpose other than the electrophotographic photosensitive member.

### EXAMPLE 1

In the present example, it was studied how the frequency and the voltage value of the pulse DC voltage affect the number of generation of arc discharge (abnormal electrical discharge) when using the plasma CVD device 2 shown in FIGS. 2 to 4, for forming film by applying a negative pulse DC voltage (see FIG. 5) between the cylindrical body 10 (supporting body 3) and the cylindrical electrode 40.

In the plasma CVD device 2, a distance D1 between the cylindrical body 10 and the cylindrical electrode 40 was set to 25 mm, and film forming conditions except the applied voltage were set as shown in the following Table 1.

TABLE 1

| | | |
|---|---|---|
| Material | SiH₄ (sccm) | 340 |
| Gas | H₂ (sccm) | 200 |
| | B₂H₆ (ppm) | 0 |
| | CH₄ (sccm) | 0 |

| | |
|---|---|
| Gas Pressure (Pa) | 60 |
| Temperature at Body (° C.) | 320 |

The negative pulse DC voltage was applied by supplying pulse voltage within the range of −4000V to −10V using the DC power source 34 connected to the cylindrical body 10 (the supporting body 3), and by grounding the cylindrical electrode 40. The frequency of the negative pulse DC voltage was set within the range of 10 kHz to 500 kHz. The duty ratio of pulse DC voltage was set to 50%.

The number of generation of arc discharge during film forming is shown in the following Table 2. Table 2 shows the number of generation of arc discharge per hour.

TABLE 2
Duty Ratio: 50%

| | | Voltage (−V) | | | | | | | | | | |
|---|---|---|---|---|---|---|---|---|---|---|---|---|
| | | 10 | 50 | 100 | 500 | 1000 | 1500 | 2000 | 2500 | 3000 | 3500 | 4000 |
| Frequency | 10 | x | 1 | 0 | 0 | 0 | 0 | 0 | 0 | 1 | 13 | 35 |
| (kHz) | 30 | x | 0 | 0 | 0 | 0 | 0 | 0 | 0 | 0 | 11 | 31 |
| | 50 | x | 0 | 0 | 0 | 0 | 0 | 0 | 0 | 0 | 13 | 26 |
| | 100 | x | 0 | 0 | 0 | 0 | 0 | 0 | 0 | 0 | 15 | 20 |
| | 300 | x | 0 | 0 | 0 | 0 | 0 | 0 | 1 | 1 | 12 | x |
| | 400 | x | 12 | 13 | 29 | 23 | 28 | 37 | 48 | x | x | x |
| | 500 | x | 18 | 23 | 26 | 29 | 33 | 41 | x | x | x | x |

x: Unstable Discharge

As can be seen from Table 2, when the frequency of the pulse DC voltage was not less than 400 kHz, the number of generation of arc discharge was significantly increased, or discharge was unstable. Further, when the DC voltage applied to the cylindrical body 10 was not less than −3000V and not more than −50V (the potential difference between the cylindrical body 10 and the cylindrical electrode 40 was not less than 50V and not more than 3000V), generation of arc discharge was substantially prevented and discharge was stabilized. On the other hand, when the DC voltage was more than −50V, discharge was unstable, while when the DC voltage was not more than −3500V, the number of generation of arc discharge was significantly increased, or discharge was unstable. Therefore, for forming deposited film by applying negative pulse DC voltage between the cylindrical body 10 and the cylindrical electrode 40, it is preferable to set the pulse DC voltage value to not less than −3000V and not more than −50V (set the potential difference between the cylindrical body 10 and the cylindrical electrode 40 to not less than 50V and not more than 3000V), and set the frequency of the DC voltage to not more than 300 kHz.

It was also studied how the frequency and the voltage value of the pulse DC voltage affect the number of generation of arc discharge (abnormal electrical discharge) when changing the distance between the cylindrical body 10 and the cylindrical electrode 40. When the distance D1 between the cylindrical body 10 and the cylindrical electrode 40 was set to smaller than 10 mm, proper workability was not obtained, and discharge was unlikely to be stable. Whereas, when the distance D1 between the cylindrical body 10 and the cylindrical electrode 40 was set to larger than 100 mm, the CVD device 2 became large, which deteriorates the productivity per unit installation area. Therefore, it is preferable to set the distance D1 between the cylindrical body 10 and the cylindrical electrode 40 to not less than 10 mm and not more than 100 mm.

### EXAMPLE 2

In the present example, it was studied how the duty ratio of the pulse DC voltage affects the number of generation of arc discharge (abnormal electrical discharge) when using the plasma CVD device 2 shown in FIGS. 2 to 4, for forming film by applying a negative pulse DC voltage between the cylindrical body 10 (supporting body 3) and the cylindrical electrode 40.

The duty ratio of the pulse DC voltage was set within the range of 10% to 95%, and the frequency and the voltage value of the pulse DC voltage were set to 30 kHz and −1000V, respectively. The conditions of film forming other than the applied voltage were the same as Example 1.

The number of generation of arc discharge during film forming is shown in the following Table 3. Table 3 shows the number of generation of arc discharge per hour.

TABLE 3
Frequency: 300 kHz, Potential Difference: −1000 V

| | Duty Ratio (%) | | | | | | | | | |
|---|---|---|---|---|---|---|---|---|---|---|
| | 10 | 20 | 30 | 40 | 50 | 60 | 70 | 80 | 90 | 95 |
| Number of | x | 0 | 0 | 0 | 0 | 0 | 0 | 0 | 1 | 36 |
| Generation | | | | | | | | | | |
| of Arc | | | | | | | | | | |
| Discharge | | | | | | | | | | |

x: Unstable Discharge

As can be seen from Table 3, when the duty ratio was 10%, discharge was unstable, while when the duty ratio was 95%, the number of generation of arc discharge was significantly increased. On the other hand, when the duty ratio was within the range of 20% to 90%, generation of arc discharge was substantially prevented and stable glow discharge was obtained. Therefore, for forming film by applying negative pulse DC voltage, it is preferable to set the duty ratio of the pulse DC voltage within the range of 20% to 90%.

### EXAMPLE 3

In the present example, it was studied how the value of the pulse DC voltage (the pulse difference between the cylindrical electrode 40 and the cylindrical body 10 (supporting body 3)) affects film forming rate when using the plasma CVD device 2 shown in FIGS. 2 to 4, for forming film by applying a negative pulse DC voltage between the cylindrical body 10 (supporting body 3) and the cylindrical electrode 40.

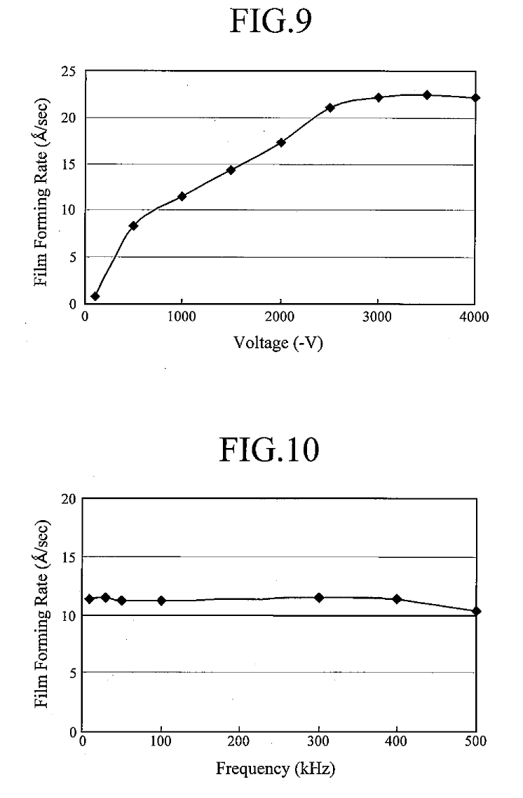

The value of the pulse DC voltage was set within the range of 10V to 4000V, and the frequency and the duty ratio were set to 30 kHz and 50%, respectively. The conditions of film forming other than the applied voltage were the same as Example 1. The measurement results of the film forming rate are shown in FIG. 9.

As can be seen from FIG. 9, as the value of negative pulse DC voltage (−V) became larger, the film forming rate became higher. Therefore, for forming film by applying negative pulse DC voltage, in view of film forming rate, it is preferable to set the value of the pulse DC voltage (−V) (the pulse difference between the cylindrical electrode 40 and the cylindrical body 10 (supporting body 3)) to not less than 500V.

### EXAMPLE 4

In the present example, it was studied how the frequency of the pulse DC voltage affects film forming rate when using the plasma CVD device 2 shown in FIGS. 2 to 4, for forming film by applying a negative pulse DC voltage between the cylindrical body 10 (supporting body 3) and the cylindrical electrode 40.

The frequency of the pulse DC voltage was set within the range of 10 kHz to 500 kHz, and the pulse DC voltage and the duty ratio were set to −1000V and 50%, respectively. The conditions of film forming other than the applied voltage were the same as Example 1. The measurement results of the film forming rate are shown in FIG. 10.

As can be seen from FIG. 10, the frequency of negative pulse DC voltage did not largely affect the film forming rate, at least in the present example.

### EXAMPLE 5

In the present example, evaluations were made on film thickness distribution, charging characteristic, and luminous sensitivity characteristic, as well as image property of images formed by an a-Si photosensitive member, using a-Si photosensitive drums (drums 1, 2 according to the present invention), made by applying a negative pulse DC voltage using the plasma CVD device shown in FIGS. 2 to 4.

In making the present drums 1, 2, two cylindrical bodies 10 made of Al, each having a dimension of φ30×340 mm, were stacked together with the dummy bodies 38A-38C, and the rotation speed of the cylindrical bodies 10 was set to 10 rpm. In the plasma CVD device 2, the distance D1 between the cylindrical body 10 and the cylindrical electrode 40 was set to 25 mm, and the cylindrical electrode 40 was grounded. The film forming conditions are shown in Table 4.

TABLE 4
Drums 1, 2 according to the present invention

| | | Anti-charge | | |
|---|---|---|---|---|
| | | Injection | Photoconductive | Surface |
| Type of Layers | | Layer | Layer | Layer |
| Material | SiH₄ | 170 | 340 | 30 |
| Gas | (sccm) | | | |
| | H₂ | 200 | 200 | 0 |
| | (sccm) | | | |
| | B₂H₆ | 1150 | 0.3 | 0 |
| | (ppm) | | | |
| | CH₄ | 0 | 0 | 600 |
| | (sccm) | | | |

| | | | |
|---|---|---|---|
| Gas Pressure (Pa) | 80 | 80 | 86.5 |
| Temperature of | 300 | 320 | 250 |
| Body (° C.) | | | |
| DC Voltage (V) | −665 | −735 | −280 |
| Film Thickness (μm) | 5 | 14 | 1 |

Further, photosensitive drums (drums 1, 2 as comparative examples) were made by applying AC voltage (13.56 MHz) using a conventional plasma CVD device, under conditions shown in Table 5. Similarly to the drums 1, according to the present invention, evaluations were made on film thickness distribution, charging characteristic, and luminous sensitivity characteristic, as well as image property of images formed by the drums 1, 2 as comparative examples. The film forming conditions of the drums 1, 2 as comparative examples are shown in Table 5.

TABLE 5
Drums 1, 2 as Comparative Examples

| | | Anti-charge | | |
|---|---|---|---|---|
| | | Injection | Photoconductive | Surface |
| Type of Layers | | Layer | Layer | Layer |
| Material | SiH₄ | 170 | 340 | 30 |
| Gas | (sccm) | | | |
| | H₂ | 200 | 200 | 0 |
| | (sccm) | | | |
| | B₂H₆ | 1150 | 0.3 | 0 |
| | (ppm) | | | |
| | CH₄ | 0 | 0 | 600 |
| | (sccm) | | | |

| | | | |
|---|---|---|---|
| Gas Pressure (Pa) | 60 | 60 | 80 |
| Temperature of | 300 | 320 | 250 |
| Body (° C.) | | | |
| DC Voltage (V) | 180 | 360 | 200 |
| Film Thickness (μm) | 5 | 14 | 1 |

(Evaluation of Film Thickness Distribution)

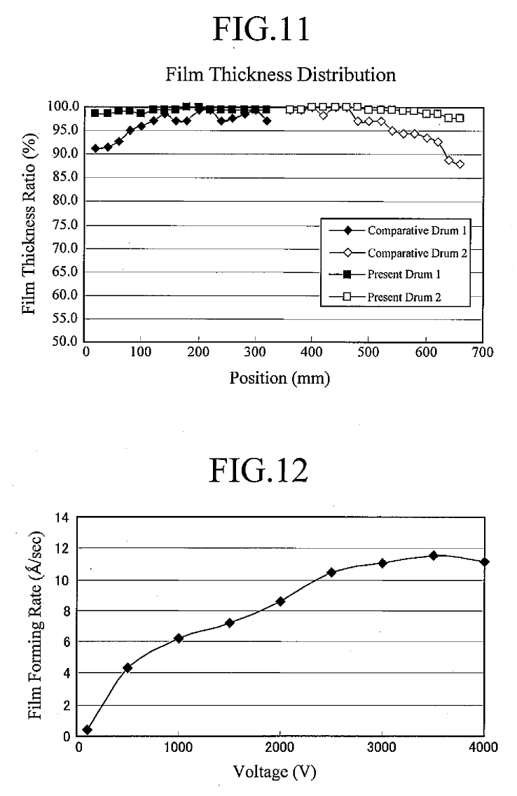

The film thickness distribution of the present drums 1, 2 and the comparative drums 1, 2 was evaluated by cutting the deposited film by 5 mm square, several times in the axial direction, and measuring the film thickness by XPS (X-ray photoelectron spectroscopy) analysis. Measurement Results of film thickness of the drums are shown in FIG. 11. In FIG. 11, position on the horizontal axis indicates the distance from the top end of the upper drum stacked in the CVD device (including the length of the intermediate dummy body 38B), and film thickness ratio on the horizontal axis indicates the ratio (%) of film thickness at each position to the maximum film thickness as seen in the axial direction.

As can be seen from FIG. 11, the present drums 1, 2 had less variation in thickness as seen in the axial direction of the drums, in comparison with the comparative drums 1, 2 made by conventional AC voltage application. Especially, variation in thickness at the ends of the drums was reduced.

(Evaluation of Charging Characteristic and Luminous Sensitivity)

The charging characteristic was evaluated by measuring voltage value when charging the present drums 1, 2 and the comparative drums 1, 2 using a corona charging mechanism to which +6 kV voltage was applied. The charging characteristic was evaluated by checking charging ability and variation in charging ability in the axial and the circumferential directions of the drums. The evaluation results of the charging characteristic are shown in the following Table 6.

The luminous sensitivity characteristic was evaluated by checking luminous sensitivity and residual potential. The luminous sensitivity was checked by measuring half-light exposure (light exposure required to reduce charging voltage by half (125V)) when irradiating a charged drum with monochromatic light dispersed into light with center wavelength of 670 nm and half bandwidth of 1 nm. The residual potential was checked by measuring voltage at the drums after irradiating the above monochromatic light at 1.2 μJ/cm². Evaluation results of the luminous sensitivity characteristic (luminous sensitivity and residual potential) are shown in the following Table 6.

TABLE 6

| | Present | | Comparative | |
|---|---|---|---|---|
| | Photosensitive | | Photosensitive | |
| | Member | | Member | |
| Evaluation Items | Drum 1 | Drum 2 | Drum 1 | Drum 2 |
| Charging Ability (V) | 251 | 253 | 253 | 255 |
| Variation in Charging | 2 | 3 | 9 | 12 |
| Ability in Axial | | | | |
| Direction (V) | | | | |
| Variation in Charging | 3 | 2 | 7 | 8 |
| Ability in | | | | |
| Circumferential | | | | |
| Direction (V) | | | | |
| Sensitivity (μJ/cm²) | 0.40 | 0.41 | 0.40 | 0.43 |
| Residual | 2 | 3 | 7 | 8 |
| Potential (V) | | | | |

As can be seen from Table 6, the present drums 1, had enhanced charging characteristic, in which the charging ability was the same as that at the comparative drums 1, 2, and the variation in charging ability in the axial and circumferential directions of the drums was smaller than that at the comparative drums 1, 2. Further, the present drums 1, 2 had also enhanced luminous sensitivity characteristic, in which luminous sensitivity was the same as that at the comparative drums 1, 2, and the residual potential was smaller than that at the comparative drums 1, 2.

(Evaluation of Image Property)

The image property was evaluated by incorporating the present drums 1, 2 and the comparative drums 1, 2, in a multifunction device KM-2550 manufactured by Kyocera Mita Corporation for continually printing on A4 paper, and by checking black spots on full-page white images (solid white images) and variation in halftone images, at the beginning and after printing 30 thousands copies. The check results were marked according to evaluation standards shown in the following Table 7, and the evaluation results are shown in the following Table 8.

TABLE 7

| | |
|---|---|
| | Variation in Halftone |
| Black Spots | Image |

| | | | |
|---|---|---|---|
| A | None | A | None |
| B | Slight | B | Slight |
| C | Without Problem in | C | Without Problem in |
| | Practical Use | | Practical Use |
| D | No Practical Use | D | No Practical Use |

TABLE 8

| | Present Photosensitive | | | | Comparative | | | |
|---|---|---|---|---|---|---|---|---|
| | Member | | | | Photosensitive Member | | | |
| | Drum 1 | | Drum 2 | | Drum 1 | | Drum 2 | |
| | | 30,000 | | 30,000 | | 30,000 | | 30,000 |
| | Beginning | Copies | Beginning | Copies | Beginning | Copies | Beginning | Copies |
| Black | A | A | A | A | B | B | B | B |
| Spots | | | | | | | | |
| Variation | A | A | A | A | C | C | C | C |
| in | | | | | | | | |
| Halftone | | | | | | | | |
| Image | | | | | | | | |

As can be seen from Table 8, the present drums 1, 2 had enhanced image property at the beginning and after printing 30 thousands copies, without black spots in white images and variation in halftone images, differently from the comparative drums 1, 2.

### EXAMPLE 6

In the present example, similarly to the Example 1, it was studied how the frequency and the voltage value of the pulse DC voltage affect the number of generation of arc discharge (abnormal electrical discharge) when using the plasma CVD device 2 shown in FIGS. 2 to 4, for forming film by applying a positive pulse DC voltage (see FIG. 6) between the cylindrical body 10 (supporting body 3) and the cylindrical electrode 40.

The positive pulse DC voltage was set to have voltage within a range of 10V to 4000V, frequency ranging within 10 kHz to 500 kHz, and duty ratio of 50%.

The number of generation of arc discharge during film forming is shown in the following Table 9. Table 9 shows the number of generation of arc discharge per hour.

TABLE 9
Duty Ratio: 50%

| | | Voltage (V) | | | | | | | | | | |
|---|---|---|---|---|---|---|---|---|---|---|---|---|
| | | 10 | 50 | 100 | 500 | 1000 | 1500 | 2000 | 2500 | 3000 | 3500 | 4000 |
| Frequency | 10 | x | 1 | 0 | 0 | 0 | 0 | 0 | 0 | 2 | 14 | 46 |
| (kHz) | 30 | x | 0 | 0 | 0 | 0 | 0 | 0 | 0 | 1 | 12 | 45 |
| | 50 | x | 0 | 0 | 0 | 0 | 0 | 0 | 0 | 0 | 15 | 31 |
| | 100 | x | 0 | 0 | 0 | 0 | 0 | 0 | 0 | 0 | 16 | 26 |
| | 300 | x | 0 | 0 | 0 | 0 | 0 | 0 | 1 | 2 | 20 | x |
| | 400 | x | 12 | 18 | 24 | 26 | 30 | 55 | 60 | x | x | x |
| | 500 | x | 19 | 26 | 33 | 36 | 38 | 58 | x | x | x | x |

x: Unstable Discharge

As can be seen from Table 9, when the frequency of the pulse DC voltage was not less than 400 kHz, the number of generation of arc discharge was significantly increased, or discharge was unstable. Further, when the DC voltage applied to the cylindrical body 10 was not less than 50V and not more than 3000V (the potential difference between the cylindrical body 10 and the cylindrical electrode 40 was not less than 50V and not more than 3000V), generation of arc discharge was substantially prevented and discharge was stabilized. On the other hand, when the voltage value (potential difference) was less than 50V, discharge was unstable, while when the voltage value (potential difference) was not less than 3500V, the number of generation of arc discharge was significantly increased, or discharge was unstable. Therefore, for forming deposited film by applying positive pulse DC voltage between the cylindrical body 10 and the cylindrical electrode 40, it is preferable to set the pulse DC voltage value (potential difference between the cylindrical body 10 and the cylindrical electrode 40) to not less than 50V and not more than 3000V, and set the frequency of the DC voltage to not more than 300 kHz.

It was also studied how the frequency and the voltage value of the pulse DC voltage affect the number of generation of arc discharge (abnormal electrical discharge) when changing the distance D1 between the cylindrical body 10 and the cylindrical electrode 40. When the distance D1 between the cylindrical body 10 and the cylindrical electrode 40 was set to smaller than 10 mm, proper workability was not obtained, and discharge was unlikely to be stable. Whereas, when the distance D1 between the cylindrical body 10 and the cylindrical electrode 40 was set to larger than 100 mm, the CVD device 2 became large, which deteriorates the productivity per unit installation area. Therefore, it is preferable to set the distance D1 between the cylindrical body 10 and the cylindrical electrode 40 to not less than 10 mm and not more than 100 mm.

### EXAMPLE 7

In the present example, it was studied how the duty ratio of the pulse DC voltage affects the number of generation of arc discharge (abnormal electrical discharge) when using the plasma CVD device 2 shown in FIGS. 2 to 4, for forming film by applying a positive pulse DC voltage (see FIG. 6) between the cylindrical body 10 (supporting body 3) and the cylindrical electrode 40.

The duty ratio of the pulse DC voltage was set within the range of 10% to 95%, and the frequency and the voltage value of the pulse DC voltage were set to 30 kHz and 1000V, respectively. The conditions of film forming other than the applied voltage were the same as Example 1 (Example 6).

The number of generation of arc discharge during film forming is shown in the following Table 10. Table 10 shows the number of generation of arc discharge per hour.

TABLE 10

| | Duty Ratio (%) | | | | | | | | | |
|---|---|---|---|---|---|---|---|---|---|---|
| | 10 | 20 | 30 | 40 | 50 | 60 | 70 | 80 | 90 | 95 |
| Number of | x | 0 | 0 | 0 | 0 | 0 | 0 | 0 | 1 | 45 |
| Arc | | | | | | | | | | |
| Discharge | | | | | | | | | | |

x: Unstable Discharge

As can be seen from Table 10, when the duty ratio was 10%, discharge was unstable, while when the duty ratio was 95%, the number of generation of arc discharge was significantly increased. On the other hand, when the duty ratio was within the range of 20% to 95%, generation of arc discharge was substantially prevented and stable glow discharge was obtained. Therefore, for forming film by applying positive pulse DC voltage, it is preferable to set the duty ratio of the pulse DC voltage within the range of 20% to 90%.

### EXAMPLE 8

In the present example, it was studied how the value of the pulse DC voltage (the pulse difference between the cylindrical electrode 40 and the cylindrical body 10 (supporting body 3)) affects film forming rate when using the plasma CVD device 2 shown in FIGS. 2 to 4, for forming film by applying a positive pulse DC voltage between the cylindrical body 10 (supporting body 3) and the cylindrical electrode 40.

The value of the pulse DC voltage was set within the range of 10V to 4000V, and the frequency and the duty ratio were set to 30 kHz and 50%, respectively. The conditions of film forming other than the applied voltage were the same as Example 1 (Example 6). The measurement results of the film forming rate are shown in FIG. 12.

As can be seen from FIG. 12, as the value of positive pulse DC voltage (potential difference) became larger, the film forming rate became higher. Therefore, for forming film by applying positive pulse DC voltage, in view of film forming rate, it is preferable to set the value of the pulse DC voltage (potential difference) to not less than 500V.

### EXAMPLE 9

In the present example, similarly to Example 4, it was studied how the frequency of the pulse DC voltage affects film forming rate when using the plasma CVD device 2 shown in FIGS. 2 to 4, for forming film by applying a positive pulse DC voltage (see FIG. 6) between the cylindrical body 10 (supporting body 3) and the cylindrical electrode 40.

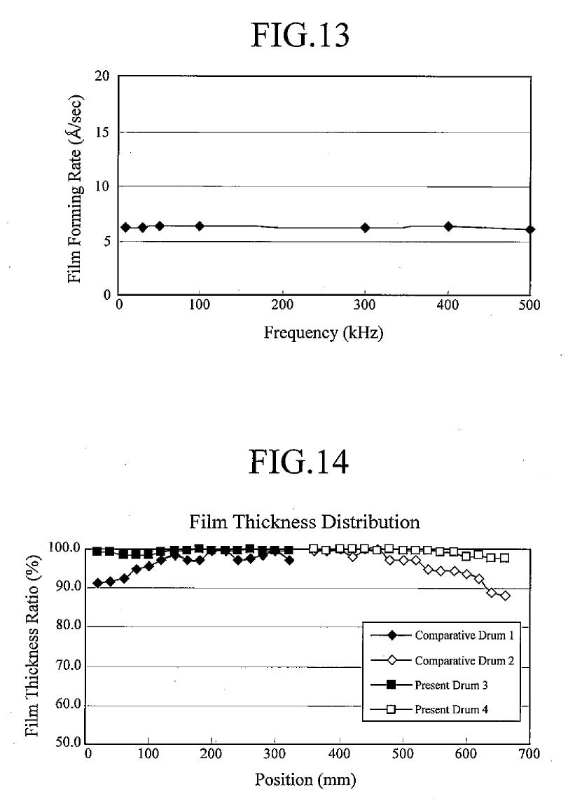

The frequency of the pulse DC voltage was set within the range of 10 kHz to 500 kHz, and the pulse DC voltage and the duty ratio were set to 1000V and 50%, respectively. The conditions of film forming other than the applied voltage were the same as Example 1 (Example 6). The measurement results of the film forming rate are shown in FIG. 13.

As can be seen from FIG. 13, the frequency of positive pulse DC voltage did not largely affect the film forming rate.

### EXAMPLE 10

In the present example, similarly to Example 5, evaluations were made on film thickness distribution, charging characteristic, and luminous sensitivity characteristic, as well as image property of images formed by an a-Si photosensitive member, using a-Si photosensitive drums (drums 3, 4 according to the present invention), made by the plasma CVD device 2 shown in FIGS. 2 to 4.

In making the present drums 3, 4, two cylindrical bodies 10 made of Al, each having a dimension of φ30×340 mm, were stacked together with the dummy bodies 38A-38C, and the rotation speed of the cylindrical bodies 10 was set to 10 rpm. In the plasma CVD device 2, the distance D1 between the cylindrical body 10 and the cylindrical electrode 40 was set to 25 mm, and the cylindrical electrode 40 was grounded. The film forming conditions are shown in the following Table 11. Specifically, a positive DC voltage was applied for forming the anti-charge injection layer 11 and the photoconductive layer 12, while a negative DC voltage was applied for forming the surface layer 13.

TABLE 11
Drums 3, 4 according to the present invention

| | | Anti-charge | | |
|---|---|---|---|---|
| | | Injection | Photoconductive | Surface |
| Type of Layers | | Layer | Layer | Layer |
| Material | SiH₄ | 170 | 340 | 30 |
| Gas | (sccm) | | | |
| | H₂ | 200 | 200 | 0 |
| | (sccm) | | | |
| | B₂H₆ | 1150 | 0.3 | 0 |
| | (ppm) | | | |
| | CH₄ | 0 | 0 | 600 |
| | (sccm) | | | |

| | | | |
|---|---|---|---|
| Gas Pressure (Pa) | 80 | 80 | 86.5 |
| Temperature of | 300 | 320 | 250 |
| Body (° C.) | | | |
| DC Voltage (V) | 664 | 732 | −280 |
| Film Thickness (μm) | 5 | 14 | 1 |

Evaluation results of film thickness distribution, charging characteristic and luminous sensitivity characteristic, and image property are respectively shown in FIG. 14, the following Table 12 and Table 13. In FIG. 14, Table 12 and Table 13, evaluation results of the comparative drums 1, 2 in Example 5 are also shown. Evaluation standards are the same as Example 5, as shown in Table 7.

TABLE 12

| | |
|---|---|
| Present | Comparative |
| Photosensitive | Photosensitive |
| Member | Member |

| Evaluation Items | Drum 3 | Drum 4 | Drum 1 | Drum 2 |
|---|---|---|---|---|
| Charging Ability (V) | 248 | 250 | 253 | 255 |
| Variation in | 1 | 2 | 9 | 12 |
| Charging Ability in | | | | |
| Axial Direction (V) | | | | |
| Variation in | 2 | 3 | 7 | 8 |
| Charging Ability in | | | | |
| Circumferential | | | | |
| Direction (V) | | | | |
| Sensitivity (μJ/cm²) | 0.42 | 0.40 | 0.40 | 0.43 |
| Residual | 3 | 2 | 7 | 8 |
| Potential (V) | | | | |

TABLE 13

| | Present | | | | Comparative | | | |
|---|---|---|---|---|---|---|---|---|
| | Photosensitive Member | | | | Photosensitive Member | | | |
| | Drum 3 | | Drum 4 | | Drum 1 | | Drum 2 | |
| | | 30,000 | | 30,000 | | 30,000 | | 30,000 |
| | Beginning | Copies | Beginning | Copies | Beginning | Copies | Beginning | Copies |
| Black | A | A | A | A | B | B | B | B |
| Spots | | | | | | | | |
| Variation | A | A | A | A | C | C | C | C |
| in | | | | | | | | |
| Halftone | | | | | | | | |
| Image | | | | | | | | |

As can be seen from FIG. 14, the present drums 3, 4 had less variation in thickness as seen in the axial direction of the drums, in comparison with the comparative drums 1, 2 made by conventional AC voltage application. Especially, variation in thickness at the ends of the drums was reduced.

As can be seen from Table 12, the present drums 3, 4 had enhanced charging characteristic, in which the charging ability was the same as that at the comparative drums 1, 2, and the variation in charging ability in the axial and circumferential directions of the drums was smaller than that in the comparative drums 1, 2. Further, the present drums 3, 4 had also enhanced luminous sensitivity characteristic, in which the luminous sensitivity was the same as that at the comparative drums 1, 2, and the residual potential was smaller than that in the comparative drums 1, 2.

As can be seen from Table 13, the present drums 3, 4 had enhanced image property at the beginning and after printing 30 thousands copies, without black spots in white images and variation in halftone images, differently from the comparative drums 1, 2.

### EXAMPLE 11

In the present example, it was studied how the frequency and the voltage of the pulse DC voltage affect the number of generation of arc discharge (abnormal electrical discharge) when using the plasma CVD device 2′ shown in FIGS. 7 and 8, for forming film by applying a negative pulse DC voltage (see FIG. 5) between each of the five sets of the cylindrical bodies 10 (supporting bodies 3) and each of the cylindrical electrode 40 and the central electrode 8.

In the plasma CVD device 2′, a distance D1 between each of the cylindrical bodies 10 and the cylindrical electrode 40, a distance D5 between the adjacent cylindrical bodies 10, and a distance D6 between each of the cylindrical bodies 10 and the central electrode 8 were respectively set to 36 mm, 40 mm, and 25 mm. Film forming conditions except the applied voltage were set the same as Example 1, as shown in Table 1.

The negative pulse DC voltage was applied by supplying pulse voltage within the range of −4000V to −10V using the DC power source 34 connected to the cylindrical bodies 10 (the supporting bodies 3), and by grounding the cylindrical electrode 40 and the central electrode 8. The frequency of the negative pulse DC voltage was set within the range of 10 kHz to 500 kHz. The duty ratio of pulse DC voltage was set to 50%.

The number of generation of arc discharge during film forming is shown in the following Table 14. Table 1 shows the number of generation of arc discharge per hour.

TABLE 14
Duty Ratio: 50%

| | | Voltage (−V) | | | | | | | | | | |
|---|---|---|---|---|---|---|---|---|---|---|---|---|
| | | 10 | 50 | 100 | 500 | 1000 | 1500 | 2000 | 2500 | 3000 | 3500 | 4000 |
| Frequency | 10 | x | 2 | 0 | 0 | 0 | 0 | 0 | 0 | 2 | 15 | 38 |
| (kHz) | 30 | x | 0 | 0 | 0 | 0 | 0 | 0 | 0 | 1 | 13 | 32 |
| | 50 | x | 0 | 0 | 0 | 0 | 0 | 0 | 0 | 0 | 11 | 27 |
| | 100 | x | 0 | 0 | 0 | 0 | 0 | 0 | 0 | 1 | 13 | 23 |
| | 300 | x | 0 | 0 | 0 | 0 | 0 | 0 | 1 | 1 | 4 | x |
| | 400 | x | 14 | 16 | 23 | 25 | 32 | 41 | 56 | x | x | x |
| | 500 | x | 23 | 25 | 28 | 31 | 28 | 43 | x | x | x | x |

x: Unstable Discharge

As can be seen from Table 14, when the frequency of the pulse DC voltage was not less than 400 kHz, the number of generation of arc discharge was significantly increased, or discharge was unstable. Further, when the DC voltage applied to the cylindrical bodies 10 was not less than −3000V and not more than −50V (the potential difference between each of the cylindrical bodies 10 and each of the cylindrical electrode 40 and the central electrode 8 was not less than 50V and not more than 3000V) generation of arc discharge was substantially prevented and discharge is stabilized. On the other hand, when the DC voltage was more than −50V, discharge was unstable, while when the DC voltage was not more than −3500V, the number of generation of arc discharge was significantly increased, or discharge was unstable. Therefore, for forming deposited film by applying negative pulse DC voltage between each of the cylindrical bodies 10 and each of the cylindrical electrode 40 and the central electrode 8, it is preferable to set the pulse DC voltage value to not less than −3000V and not more than −50V (set the potential difference between each of the cylindrical bodies 10 and each of the cylindrical electrode 40 and the central electrode 8 to not less than 50V and not more than 3000V), and set the frequency of the DC voltage to not more than 300 kHz.

It was also studied how the frequency and the voltage value of the pulse DC voltage affect the number of generation of arc discharge (abnormal electrical discharge) when changing the distance D1 between each of the cylindrical bodies 10 and the cylindrical electrode 40, the distance D5 between the adjacent cylindrical bodies 10, and the distance D6 between each of the cylindrical bodies 10 and the central electrode 8. When the distance D1 between each of the cylindrical bodies 10 and the cylindrical electrode 40, the distance D5 between the adjacent cylindrical bodies 10, and the distance D6 between each of the cylindrical bodies 10 and the central electrode 8 were respectively set within ranges of 25 mm to 60 mm, 20 mm to 40 mm, and 30 mm to 100 mm, preferable results were obtained.

On the other hand, when the distance D1 between each of the cylindrical bodies 10 and the cylindrical electrode 40, the distance D5 between the adjacent cylindrical bodies 10, and the distance D6 between each of the cylindrical bodies 10 and the central electrode 8 were respectively set to be less than 25 mm, 40 mm, and 100 mm, proper workability was not obtained, and discharge was unlikely to be stable. Whereas, when the distance D1 between each of the cylindrical bodies 10 and the cylindrical electrode 40, the distance D5 between the adjacent cylindrical bodies 10, and the distance D6 between each of the cylindrical bodies 10 and the central electrode 8 were respectively set to be larger than 60 mm, 40 mm, and 100 mm, the CVD device 2′ became large, which deteriorates the productivity per unit installation area.

Further, even when omitting the central electrode 8 in the plasma CVD device 2′ shown in FIGS. 7 and 8, the same results were obtained with respect to the distance D1 between each of the cylindrical bodies 10 and the cylindrical electrode 40, and the distance D5 between the adjacent cylindrical bodies 10.

### EXAMPLE 12

In the present example, it was studied how the duty ratio of the pulse DC voltage affects the number of generation of arc discharge (abnormal electrical discharge) when using the plasma CVD device 2′ shown in FIGS. 7 and 8, for forming film by applying a negative pulse DC voltage between each of the cylindrical bodies 10 (supporting bodies 3) and each of the cylindrical electrode 40 and the central electrode 8.

The duty ratio of the pulse DC voltage was set within the range of 10% to 95%, and the frequency and the voltage value of the pulse DC voltage were set to 30 kHz and 1000V, respectively. The conditions of film forming other than the applied voltage were the same as Example 11.

The number of generation of arc discharge during film forming is shown in the following Table 15. Table 15 shows the number of generation of arc discharge per hour.

TABLE 15
Frequency: 30 kHz, Potential Difference: −1000 V

| | Duty Ratio (%) | | | | | | | | | |
|---|---|---|---|---|---|---|---|---|---|---|
| | 10 | 20 | 30 | 40 | 50 | 60 | 70 | 80 | 90 | 95 |
| Number of | x | 0 | 0 | 0 | 0 | 0 | 0 | 0 | 1 | 42 |
| Arc | | | | | | | | | | |
| Discharge | | | | | | | | | | |

x: Unstable Discharge

As can be seen from Table 15, when the duty ratio was 10%, discharge was unstable, while when the duty ratio was 95%, the number of generation of arc discharge was significantly increased. On the other hand, when the duty ratio was within the range of 20% to 95%, generation of arc discharge was substantially prevented and stable glow discharge is obtained. Therefore, for forming film by applying negative pulse DC voltage, it is preferable to set the duty ratio of the pulse DC voltage within the range of 20% to 90%.

### EXAMPLE 13

In the present example, it was studied how the value of the pulse DC voltage (the pulse difference between each of the cylindrical bodies 10 (supporting bodies 3) and each of the cylindrical electrode 40 and the central electrode 8) affects film forming rate when using the plasma CVD device 2′ shown in FIGS. 7 and 8, for forming film by applying a negative pulse DC voltage between each of the cylindrical bodies 10 (supporting bodies 3) and each of the cylindrical electrode 40 and the central electrode 8.

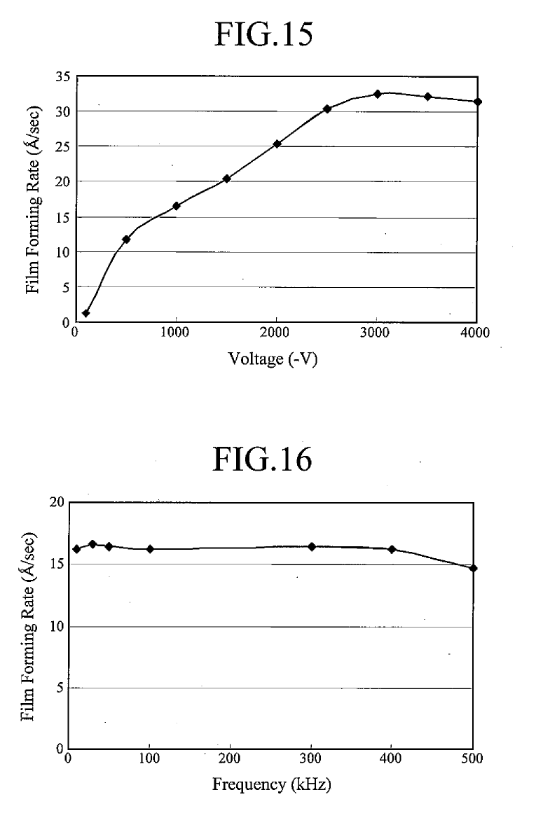

The value of the pulse DC voltage of the pulse DC voltage was set within the range of −4000V to −10V, and the frequency and the duty ratio were set to 30 kHz and 50%, respectively. The conditions of film forming other than the applied voltage were the same as Example 1. The measurement results of the film forming rate are shown in FIG. 15.

As can be seen from FIG. 15, as the potential difference (−V) of negative pulse DC voltage became larger, the forming film rate became higher. Therefore, in view of film forming rate, it is preferable to set potential difference (−V) of the pulse DC voltage to not less than 500V.

### EXAMPLE 14

In the present example, it was studied how the frequency of the pulse DC voltage affects film forming rate when using the plasma CVD device 2′ shown in FIGS. 7 and 8, for forming film by applying a negative pulse DC voltage (see FIG. 6) between each of the cylindrical bodies 10 (supporting bodies 3) and each of the cylindrical electrode 40 the central electrode 8.

The frequency of the pulse DC voltage was set within the range of 10 kHz to 500 kHz, and the pulse DC voltage and the duty ratio were set to −1000V and 50%, respectively. The conditions of film forming other than the applied voltage were the same as Example 1. The measurement results of the film forming rate are shown in FIG. 16.

As can be seen from FIG. 16, the frequency of negative pulse DC voltage did not largely affect the film forming rate.

### EXAMPLE 15

In the present example, similarly to Example 5, evaluations were made on film thickness distribution, charging characteristic, and luminous sensitivity characteristic, as well as image property of images formed by an a-Si photosensitive member, using a-Si photosensitive drums (drums 5, 6 according to the present invention), made by the plasma CVD device 2′ shown in FIGS. 7 and 8.

In making the present drums 5, 6, in each of the five supporting bodies 3, two cylindrical bodies 10 made of Al, each having a dimension of φ30×340 mm, were stacked together with the dummy bodies 38A-38C, and the rotation speed of the cylindrical bodies 10 was set to 10 rpm. The film forming conditions are shown in Table 16.

TABLE 16
Drums 5, 6 according to the Present Invention

| | | Anti-charge | | |
|---|---|---|---|---|
| | | Injection | Photoconductive | Surface |
| Type of Layers | | Layer | Layer | Layer |
| Material | SiH₄ | 170 | 340 | 30 |
| Gas | (sccm) | | | |
| | H₂ | 200 | 200 | 0 |
| | (sccm) | | | |
| | B₂H₆ | 1150 | 0.3 | 0 |
| | (ppm) | | | |
| | CH₄ | 0 | 0 | 600 |
| | (sccm) | | | |

| | | | |
|---|---|---|---|
| Gas | 60 | 60 | 80 |
| Pressure (Pa) | | | |
| Temperature of | 300 | 320 | 250 |
| Body (° C.) | | | |
| DC Voltage (V) | −950 | −1050 | −400 |
| Film Thickness (μm) | 5 | 14 | 1 |

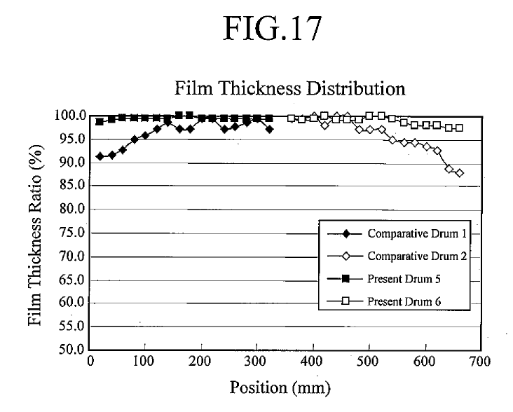

Evaluation results of film thickness distribution, charging characteristic and luminous sensitivity characteristic, and image property are respectively shown in FIG. 17, the following Table 17 and Table 18. In FIG. 17, Table 17 and Table 18, evaluation results of the comparative drums 1, 2 in Example 5 are also shown. Evaluation standards are the same as Example 5, as shown in Table 7.

TABLE 17

| | |
|---|---|
| Present | Comparative |
| Photosensitive | Photosensitive |
| Member | Member |

| Evaluation Items | Drum 5 | Drum 6 | Drum 1 | Drum 2 |
|---|---|---|---|---|
| Charging Ability (V) | 252 | 254 | 253 | 255 |
| Variation in | 3 | 2 | 9 | 12 |
| Charging Ability in | | | | |
| Axial Direction (V) | | | | |
| Variation in | 2 | 2 | 7 | 8 |
| Charging Ability in | | | | |
| Circumferential | | | | |
| Direction (V) | | | | |
| Sensitivity (μJ/cm²) | 0.41 | 0.42 | 0.40 | 0.43 |
| Residual | 2 | 2 | 7 | 8 |
| Potential (V) | | | | |

TABLE 18

| | Present | | | | Comparative | | | |
|---|---|---|---|---|---|---|---|---|
| | Photosensitive Member | | | | Photosensitive Member | | | |
| | Drum 5 | | Drum 6 | | Drum 1 | | Drum 2 | |
| | | 30,000 | | 30,000 | | 30,000 | | 30,000 |
| | Beginning | Copies | Beginning | Copies | Beginning | Copies | Beginning | Copies |
| Black | A | A | A | A | B | B | B | B |
| Spots | | | | | | | | |
| Variation | A | A | A | A | C | C | C | C |
| in | | | | | | | | |
| Halftone | | | | | | | | |
| Image | | | | | | | | |

As can be seen from FIG. 17, the present drums 5, had less variation in thickness as seen in the axial direction of the drums, in comparison with the comparative drums 1, 2 made by conventional AC voltage application. Especially, variation in thickness at the ends of the drums was reduced.

As can be seen from Table 17, the present drums 5, had enhanced charging characteristic, in which the charging ability was the same as that at the comparative drums 1, 2, and the variation in charging ability in the axial and circumferential directions of the drums was smaller than that in the comparative drums 1, 2. Further, the present drums 5, 6 had also enhanced luminous sensitivity characteristic, in which the luminous sensitivity was the same as that at the comparative drums 1, 2, and the residual potential was smaller than that in the comparative drums 1, 2.

As can be seen from Table 18, the present drums 5, 6 had enhanced image property at the beginning and after printing 30 thousands copies, without black spots in white images and variation in halftone images, differently from the comparative drums 1, 2.

### EXAMPLE 16

In the present example, similarly to Example 5, evaluations were made on film thickness distribution, charging characteristic, and luminous sensitivity characteristic, as well as image property of images formed by an a-Si photosensitive member, using a-Si photosensitive drums (drums 7, 8 according to the present invention) having an a-C surface layer 13, made by the plasma CVD device 2 shown in FIGS. 2 to 4.

In making the present drums 7, 8, two cylindrical bodies 10 made of Al, each having a dimension of φ30×340 mm, were stacked together with the dummy bodies 38A-38C, and the rotation speed of the cylindrical bodies 10 was set to 10 rpm. In the plasma CVD device 2, the distance D1 between the cylindrical body 10 and the cylindrical electrode 40 was set to 25 mm, and the cylindrical electrode 40 was grounded. The film forming conditions are shown in the following Table 19. Specifically, a negative DC voltage was applied for forming the anti-charge injection layer 11, the photoconductive layer 12, and the surface layer 13.

TABLE 19
Drums 7, 8 according to the Present Invention

| | | Anti-charge | | |
|---|---|---|---|---|
| | | Injection | Photoconductive | Surface |
| Type of Layers | | Layer | Layer | Layer |
| Material | SiH₄ | 170 | 340 | 30 |
| Gas | (sccm) | | | |
| | H₂ | 200 | 200 | 0 |
| | (sccm) | | | |
| | B₂H₆ | 1150 | 0.3 | 0 |
| | (ppm) | | | |
| | CH₄ | 0 | 0 | 600 |
| | (sccm) | | | |

| | | | |
|---|---|---|---|
| Gas Pressure (Pa) | 80 | 80 | 86.5 |
| Temperature of | 300 | 320 | 250 |
| Body (° C.) | | | |
| DC Voltage (V) | −665 | −735 | −280 |
| Film Thickness (μm) | 5 | 14 | 0.5 |

Evaluation results of charging characteristic and luminous sensitivity characteristic, and image property are respectively shown in the following Table 20 and Table 21. In Tables 20 and 21, results of the comparative drums 1, 2 in Example 5 are also shown. Evaluation standards are the same as Example 5, as shown in Table 7.

TABLE 20

| | |
|---|---|
| Present | Comparative |
| Photosensitive | Photosensitive |
| Member | Member |

| Evaluation Items | Drum 7 | Drum 8 | Drum 1 | Drum 2 |
|---|---|---|---|---|
| Charging Ability (V) | 254 | 258 | 253 | 255 |
| Variation in | 2 | 3 | 9 | 12 |
| Charging Ability in | | | | |
| Axial Direction (V) | | | | |
| Variation in | 3 | 2 | 7 | 8 |
| Charging Ability in | | | | |
| Circumferential | | | | |
| Direction (V) | | | | |
| Sensitivity (μJ/cm²) | 0.40 | 0.41 | 0.40 | 0.43 |
| Residual | 8 | 8 | 7 | 8 |
| Potential (V) | | | | |

TABLE 21

| | Present | | | | Comparative | | | |
|---|---|---|---|---|---|---|---|---|
| | Photosensitive Member | | | | Photosensitive Member | | | |
| | Drum 7 | | Drum 8 | | Drum 1 | | Drum 2 | |
| | | 30,000 | | 30,000 | | 30,000 | | 30,000 |
| | Beginning | Copies | Beginning | Copies | Beginning | Copies | Beginning | Copies |
| Black | A | A | A | A | B | B | B | B |
| Spots | | | | | | | | |
| Variation | A | A | A | A | C | C | C | C |
| in | | | | | | | | |
| Halftone | | | | | | | | |
| Image | | | | | | | | |

As can be seen from Table 20, the present drums 7, 8 formed with the a-C surface layer 13, had enhanced charging characteristic, in which the charging ability was the same as that at the comparative drums 1, 2, and the variation in charging characteristic in the axial and circumferential directions of the drums was smaller than that in the comparative drums 1, 2. Further, the present drums 7, 8 had also enhanced luminous sensitivity characteristic, in which the luminous sensitivity was the same as that at the comparative drums 1, 2, and the residual potential was smaller than that in the comparative drums 1, 2.

As can be seen from Table 21, the present drums 7, 8 had enhanced image property at the beginning and after printing 30 thousands copies, without black spots in white images and variation in halftone images, differently the comparative drums 1, 2.

1-40. (canceled)

41. A method of forming a deposited film, comprising:
a first step for setting a deposited film forming target into a reaction chamber;
a second step for filling the reaction chamber with a reaction gas; and
a third step for applying a pulse DC voltage between one or a plurality of first conductors and a second conductor spaced from each other in the reaction chamber.

42. The method of forming a deposited film according to claim 41, wherein in the third step, a potential difference between the first conductor and the second conductor is set to not less than 50V and not more than 3000V.

43. The method of forming a deposited film according to claim 41, wherein in the third step, frequency of the pulse DC voltage applied to the first conductor and the second conductor is set to not more than 300 kHz.

44. The method of forming a deposited film according to claim 41, wherein in the third step, duty ratio of the pulse DC voltage applied to the first conductor and the second conductor is set to not less than 20% and not more than 90%.

45. The method of forming a deposited film according to claim 41, wherein in the first step, the deposited film forming target is supported by the first conductor,
wherein in the third step, the pulse DC voltage is applied to the first conductor, while the second conductor is at ground potential or reference potential.

46. The method of forming a deposited film according to claim 41, wherein in the second step, the reaction chamber has a reaction gas atmosphere in which an amorphous film containing silicon is formed on the deposited film forming target.

47. The method of forming a deposited film according to claim 41, wherein in the second step, the reaction chamber has a reaction gas atmosphere in which an amorphous film containing carbon is formed on the deposited film forming target.

48. The method of forming a deposited film according to claim 41, wherein the second step includes a step for having a reaction gas atmosphere in the reaction chamber in which an amorphous film containing silicon is formed on the deposited film forming target, and a step for having a reaction gas atmosphere in the reaction chamber in which an amorphous film containing silicon and carbon on the deposited film forming target,
wherein in the third step, a positive pulse DC voltage is applied between the first conductor and the second conductor when the reaction chamber has the reaction gas atmosphere in which the amorphous film containing silicon is formed, while a negative pulse DC voltage is applied between the first conductor and the second conductor when the reaction chamber has the reaction gas atmosphere in which the amorphous film containing silicon and carbon is formed.

49. A deposited film forming device comprising:
a reaction chamber for accommodating a deposited film forming target;
one or plurality of first conductors and a second conductor arranged in the reaction chamber;
a gas supply for supplying a reaction gas in the reaction chamber;
a voltage source for applying a DC voltage between each of the first conductors and the second conductor; and
a controller for controlling the DC voltage applied by the voltage source to be a pulse DC voltage.

50. The deposited film forming device according to claim 49, wherein the controller controls a potential difference between the first conductor and the second conductor to be not less than 50V and not more than 3000V.

51. The deposited film forming device according to claim 49, wherein the controller controls frequency of the pulse DC voltage applied to the first conductor and the second conductor to be not more than 300 kHz.

52. The deposited film forming device according to claim 49, wherein the controller controls duty ratio of the pulse DC voltage applied to the first conductor and the second conductor to be not less than 20% and not more than 90%.

53. The deposited film forming device according to claim 49, wherein the first conductor supports the deposited film forming target.

54. The deposited film forming device according to claim 49, wherein the deposited film forming target is an electrophotographic photosensitive member.

55. The deposited film forming device according to claim 49, wherein the gas supply supplies the reaction chamber with a reaction gas for forming an amorphous film containing silicon on the deposited film forming target.

56. The deposited film forming device according to claim 49, wherein the gas supply supplies the reaction chamber with a reaction gas for forming an amorphous film containing carbon on the deposited film forming target.

57. The deposited film forming device according to claim 49, wherein the gas supply supplies the reaction chamber with a reaction gas for forming an amorphous film containing silicon on the deposited film forming target, as well as with a reaction gas for forming an amorphous film containing silicon and carbon on the deposited film forming target,
wherein the controller applies a positive pulse DC voltage between the first conductor and the second conductor when the reaction chamber has the reaction gas atmosphere in which an amorphous film containing silicon is formed, while applying a negative pulse DC voltage between the first conductor and the second conductor when the reaction chamber has the reaction gas atmosphere in which an amorphous film containing silicon and carbon is formed.

58. The deposited film forming device according to claim 49, further comprising a discharger for controlling gas pressure of the reaction gas in the reaction chamber.

59. A deposited film formed by the method of forming a deposited film according to claim 41.

60. The deposited film according to claim 59, containing amorphous silicon (a-Si).

61. The deposited film according to claim 59, containing amorphous silicon carbon (a-SiC).

62. The deposited film according to claim 59, containing amorphous carbon (a-C).

63. An electrophotographic photosensitive member comprising the deposited film according to claim 59.
